(19) United States
(12) Patent Application Publication
(10) Pub. No.: US 2007/0093015 A1
(43) Pub. Date: Apr. 26, 2007

(54) Semiconductor device and method for fabricating the same

(76) Inventors: Chiaki Kudo, Hyogo (JP); Hisashi Ogawa, Osaka (JP)

Correspondence Address: MCDERMOTT WILL & EMERY LLP, 600 13TH STREET, N.W., WASHINGTON, DC, 20005-3096, US

(21) Appl. No.: 11/488,051

(22) Filed: Jul. 18, 2006

(30) Foreign Application Priority Data
Oct. 26, 2005 (JP) 2005-311552

(51) Int. Cl. H01L 21/8238; H01L 21/336

(52) U.S. Cl. 438/199; 438/257

(57) ABSTRACT

A semiconductor device includes a first field-effect transistor including a first gate electrode and a second field-effect transistor including a second gate electrode. The first gate electrode and the second gate electrode are integrated using a connecting portion and are fully silicided with a metal in such a manner that the fist and second gate electrodes have different metal contents. A diffusion preventing film for preventing the metal from diffusing between the first and second gate electrodes is formed in at least a portion of the connecting portion.

### CROSS-REFERENCE TO RELATED APPLICATION

The disclosure of Japanese Patent Application No. 2005-311552 filed in Japan on Oct. 26, 2005 including specification, drawings and claims is incorporated herein by reference in its entirety.

### BACKGROUND OF THE INVENTION

The present invention relates to semiconductor devices and methods for fabricating the devices, and particularly relates to semiconductor devices including field-effect transistors with fully-silicided (FUSI) structures and methods for fabricating the devices.

The integration degree of semiconductor elements integrated in a semiconductor integrated circuit device has increased to date. For example, a technique for miniaturizing a gate electrode of a metal-insulator-semiconductor (MIS) field-effect transistor (FET) and reducing the electrical thickness of a gate insulating film by using a material with a high dielectric constant as an insulating material of a gate insulating film is being used. However, it is generally impossible to prevent depletion from being formed in polysilicon used for the gate electrode even by impurity implantation, resulting in that this depletion causes the electrical thickness of the gate insulating film to increase. This hinders enhancement of performance of an FET.

In recent years, gate electrode structures in which depletion in gate electrodes is prevented have been proposed. Specifically, a fully-silicided (FUSI) structure obtained by causing reaction between a silicon material forming a gate electrode and a metal material and thereby changing the entire silicon material into silicide is reported as an effective technique for suppressing depletion in the gate electrode.

For example, in T. Aoyama et al., IEEE, Proposal of New HfSiON CMOS Fabrication Process (HAMDAMA) for Low Standby Power Device, 2004 (hereinafter, referred to as Literature 1), a method for forming a FUSI structure is proposed. In K. Takahashi et al., IEEE, Dual Workfunction Ni-Silicide/HfSiON Gate Stacks by Phase-Controlled Full-Silicidation (PC-FUSI) Technique for 45 nm-node LSTP and LOP Devices, 2004 (hereinafter, referred to as Literature 2), different materials are used for FUSI electrodes in an n-FET and a p-FET, e.g., NiSi is used for the n-FET and Ni₃Si is used for the p-FET, is proposed.

FIGS. 34A through 34D illustrate cross-sectional structures of a main portion in process steps of forming FUSI electrodes in a method for fabricating conventional MISFETs disclosed in Literature 1.

First, as illustrated in FIG. 34A, an isolation film 2 is formed in an upper portion of a semiconductor substrate 1 made of silicon. Thereafter, a gate insulating film 3 and a conductive polysilicon film are formed in this order on an n-FET region A and a p-FET region B of the semiconductor substrate 1 defined by the isolation film 2. Subsequently, the polysilicon film is patterned, thereby forming a first gate-electrode formation film 4A and a second gate-electrode formation film 4B in the n-FET region A and the p-FET region B, respectively. Then, insulating sidewall spacers 5 are formed on side faces of the gate-electrode formation films 4A and 4B. Subsequently, using the sidewall spacers 5 as masks, source/drain regions 6 are formed in an active region of the semiconductor substrate 1. Thereafter, an interlayer insulating film 7 is formed over the semiconductor substrate 1 to cover the gate-electrode formation films 4A and 4B and the sidewall spacers 5. Then, chemical mechanical polishing (CMP), for example, is performed on the interlayer insulating film 7, thereby exposing the gate-electrode formation films 4A and 4B.

Next, as illustrated in FIG. 34B, a resist pattern 8 for exposing the p-FET region B is formed on the interlayer insulating film 7. Then, using the resist pattern 8 as a mask, an upper portion of the second gate-electrode formation film 4B exposed from the interlayer insulating film 7 in the p-FET region B is removed by etching.

Thereafter, as illustrated in FIG. 34C, the resist pattern 8 is removed, and then a metal film 9 made of nickel is deposited over the interlayer insulating film 7 from which the gate-electrode formation films 4A and 4B are exposed.

Then, as illustrated in FIG. 34D, heat treatment is performed on the semiconductor substrate 1 to cause reaction between the gate-electrode formation films 4A and 4B of polysilicon and the metal film 9, thereby forming a first gate electrode 10A having its upper portion silicided in the n-FET region A and a fully-silicided second gate electrode 10B in the p-FET region B. In Literature 1, a lower portion of the first gate electrode 10A forming an n-FET is still polysilicon and a lower portion of the second gate electrode 10B forming a p-FET is NiSi.

In Literature 2, a thick metal film is deposited so that the entire first gate electrode 10A is made of NiSi and the entire second gate electrode 10B is made of Ni₃Si.

In addition, in forming a flip-flop circuit including an n-FET and a p-FET, a first gate electrode 14a in the n-FET region A and a second gate electrode 14b in the p-FET region B have the same potential as illustrated in FIG. 35 in some cases. In this case, to reduce the circuit area, the first gate electrode 14a and the second gate electrode 14b are formed to be integrated so that a common gate electrode 14 is formed.

Some semiconductor integrated circuits need to have relatively high resistance. In such semiconductor integrated circuits, a silicon material which is not fully silicided is used for resistors in some cases. FIG. 35 illustrates a resistor 20 formed in a resistor region C on an isolation region 12 and including: a resistor body 20a of polysilicon which is not fully silicided; and contact regions 20b which are located at both ends of the resistor body 20a and fully silicided.

In the conventional semiconductor device including the FUSI common gate electrode 14, however, it is necessary to make the metal content of a silicide material forming the second gate electrode 14b in the p-FET region B higher than that of a silicide material forming the first gate electrode 14a in the n-FET region A in some cases. In such cases, metal for silicidation can be diffused from the second gate electrode 14b having a metal content higher than that of the first gate electrode 14a into the first gate electrode 14a in a silicidation process or a subsequent heat treatment process. In the resistor 20, metal diffusion is conspicuous in the interface between the FUSI contact regions 20b and the non-FUSI resistor body 20a. Then, an intermediate phase film 14c having a metal content between the silicide material forming the first gate electrode 14a and the silicide material forming the second gate electrode 14b is formed between the first gate electrode 14a and the second gate electrode 14b in the common gate electrode 14. In the same manner, in the resistor 20, intermediate phase films 20c having a metal content between the silicide material forming the contact regions 20b and polysilicon forming the resistor body 20a are formed between the resistor body 20a and the contact regions 20b.

FIG. 36 illustrates a cross-sectional structure taken along the line XXXVI-XXXVI in FIG. 35. FIG. 36 shows a case where the composition of the first gate electrode 14a in the n-FET region A is NiSi and the composition of the second gate electrode 14b in the p-FET region B is Ni₃Si. As illustrated in FIG. 36, in each of the common gate electrode 14 and the resistor 20, nickel (Ni) which is a metal for silicidation is diffused from a high-concentration region to a low-concentration region so that the intermediate phase films 14c and 20c are formed.

In this manner, in FETs, for example, portions having different compositions are formed in the silicide materials which are in contact with a gate insulating film 21 between a semiconductor substrate 11 and the common gate electrode 14, thus causing the threshold voltages of the FETs to vary. To avoid the variation of the threshold voltages caused by Ni diffusion, it is necessary to separate the first gate electrode 14a in the n-FET region A and the second gate electrode 14b in the p-FET region B and connect these electrodes through interconnection or to keep a sufficient distance between the n-FET region A and the p-FET region B. These methods have another problem that the circuit area increases. With respect to the resistor 20, variation of the intermediate phase films 20c occurs among the resistors 20, thus making it difficult to obtain a desired resistance value.

### SUMMARY OF THE INVENTION

It is therefore an object of the present invention to prevent metal diffusion in a FUSI structure having different metal contents, especially in an integrated gate electrode.

To achieve the object, in a semiconductor device and a method for fabricating the device according to the present invention, a diffusion preventing region for preventing diffusion of metal for silicidation is formed in the boundary (i.e., a connecting portion) between portions having different metal contents in a FUSI structure.

Specifically, a semiconductor device according to the present invention includes: a first field-effect transistor including a first gate electrode; and a second field-effect transistor including a second gate electrode, wherein the first gate electrode and the second gate electrode are integrated using a connecting portion and are fully silicided with metal in such a manner that the fist and second gate electrodes have different metal contents, and a diffusion preventing film for preventing the metal from diffusing between the first and second gate electrodes is formed in at least a portion of the connecting portion.

In the semiconductor device of the present invention, the diffusion preventing film is preferably made of a first conductor covering the entire connecting portion.

In the semiconductor device of the present invention, the diffusion preventing film is preferably made of a first conductor partially covering the connecting portion.

In this case, a second conductor film may be provided in a lower portion of the connecting portion, and the diffusion preventing film may be provided on the second conductor film.

In addition, in this case, a third conductor film may be formed on the diffusion preventing film.

Alternatively, a second conductor film may be provided in an upper portion of the connecting portion, and the diffusion preventing film may be provided under the second conductor film.

If the diffusion preventing film is made of the first conductor, the first conductor is preferably made of another metal or a metal compound which is not silicided.

In the semiconductor device of the present invention, the diffusion preventing film is preferably made of an insulator partially covering the connecting portion.

In this case, a second conductor film may be provided in a lower portion of the connecting portion, and the diffusion preventing film may be provided on the second conductor film.

In addition, in this case, a third conductor film may be formed on the diffusion preventing film.

In this case, the second conductor film is preferably made of a silicide having a metal content between a metal content of the first gate electrode and a metal content of the second gate electrode.

The third conductor film preferably contains a metal for siliciding the first gate electrode and the second gate electrode.

A second conductor film may be provided in one side of the connecting portion, and the diffusion preventing film may be formed in the other portion of the connecting portion.

In the semiconductor device of the present invention, the diffusion preventing film between the first gate electrode and the second gate electrode preferably has a cross-sectional area larger than that of the connecting portion between the first gate electrode and the second gate electrode.

In the semiconductor device of the present invention, it is preferable that one of the first and second field-effect transistors has an n-type conductivity and the other field-effect transistor has a p-type conductivity.

In this case, it is preferable that one of the first and second field-effect transistors whose first or second gate electrode has a higher metal content has a p-type conductivity, and the other field-effect transistor whose first or second gate electrode has a lower metal content has an n-type conductivity.

The semiconductor device of the present invention further preferably includes a resistor including a resistor body containing silicon and a contact region formed by fully siliciding a portion of the resistor body with the metal, and a diffusion preventing film for preventing the metal from diffusing from the contact region to the resistor body is preferably formed in a connection portion between the resistor body and the contact region.

A first method for fabricating a semiconductor device according to the present invention is a method for fabricating a semiconductor device including a first field-effect transistor including a first gate electrode and a second field-effect transistor including a second gate electrode. The method includes the steps of: (a) forming, on a semiconductor region, a silicon gate electrode made of silicon and including a first-gate-electrode region and a second-gate-electrode region; (b) forming, in a connecting portion between the first-gate-electrode region and the second-gate-electrode region in the silicon gate electrode, a first trench in which at least a portion of each of the first-gate-electrode region and the second-gate-electrode region is exposed; (c) forming, in the first trench, a diffusion preventing film for preventing diffusion of a metal for siliciding the silicon gate electrode; (d) forming a metal film on the silicon gate electrode in which the diffusion preventing film is formed; and (e) performing heat treatment on the metal film so that the first-gate-electrode region and the second-gate-electrode region are fully silicided to have different metal contents, thereby forming the first gate electrode and the second gate electrode.

In the first method, the diffusion preventing film is preferably made of another metal or a metal compound which is not silicided with the metal film.

The first method preferably further includes the step: (f) removing an upper portion of one of the first-gate-electrode region and the second-gate-electrode region in the silicon gate electrode by etching, between the steps of (a) and (d).

In the first method, the step (d) preferably includes the step of making the metal film have different thicknesses between portions on the first-gate-electrode region and the second-gate-electrode region in the silicon gate electrode.

A second method for fabricating a semiconductor device according to the present invention is a method for fabricating a semiconductor device including a first field-effect transistor including a first gate electrode and a second field-effect transistor including a second gate electrode. The method includes the steps of: (a) forming, on a semiconductor region, a silicon gate electrode made of silicon and including a first-gate-electrode region and a second-gate-electrode region; (b) forming a first trench in a connecting portion between the first-gate-electrode region and the second-gate-electrode region in the silicon gate electrode, leaving a lower portion of the connecting portion between the first-gate-electrode region and the second-gate-electrode region; (c) forming a metal film on the silicon gate electrode in which the first trench is formed; and (d) performing heat treatment on the metal film so that the first-gate-electrode region and the second-gate-electrode region are fully silicided to have different metal contents, thereby forming the first gate electrode and the second gate electrode.

The second method preferably further includes the step of: (e) forming, in the first trench, a diffusion preventing film for preventing diffusion of a metal for siliciding the silicon gate electrode, between the steps (b) and (c).

In the second method, the diffusion preventing film is preferably made of another metal or a metal compound which is not silicided.

The second method preferably further includes the step of: (f) removing an upper portion of one of the first-gate-electrode region and the second-gate-electrode region in the silicon gate electrode by etching, between the steps of (a) and (c).

In the second method, the step (c) preferably includes the step of making the metal film have different thicknesses between portions on the first-gate-electrode region and the second-gate-electrode region in the silicon gate electrode.

In the second method, in the step (b), each of the first-gate-electrode region and the second gate electrode exposed from a wall of the first trench preferably has a cross-sectional area larger than that of the connecting portion between the first gate electrode and the second-gate-electrode region.

Preferably, the second method further includes the step of: (g) selectively forming an isolation region in an upper portion of the semiconductor region, before the step (a), wherein the step (a) includes the step of forming, on the isolation region, a silicon resistor made of silicon and including a resistor body and a contact region connected to the resistor body, the step (b) includes the step of forming, in a connecting portion between the resistor body and the contact region in the silicon resistor, a second trench in which at least a portion of each of the resistor body and the contact region is exposed, the step (c) includes the step of forming the diffusion preventing film in the second trench, the step (d) includes the step of selectively forming the metal film on the contact region in the silicon resistor in which the diffusion preventing film is formed, and the step (e) includes the step of fully siliciding the contact region with the metal film through the heat treatment.

Preferably, the second method further includes the step of: (g) selectively forming an isolation region in an upper portion of the semiconductor region, before the step (a), the step (a) includes the step of forming, on the isolation region, a silicon resistor made of silicon and including a resistor body and a contact region connected to the resistor body, the step (b) includes the step of forming, in a connecting portion between the resistor body and the contact region in the silicon resistor, a second trench in which a portion of each of the resistor body and the contact region is exposed, the step (c) includes the step of selectively forming the metal film on the contact region in the silicon resistor in which the second trench is formed, and the step (d) includes the step of fully siliciding the contact region with the metal film through the heat treatment.

In this case, the step (e) preferably includes the step of forming the diffusion preventing film in the second trench.

As described above, with the semiconductor devices and the methods for fabricating the devices according to the present invention, metal diffusion occurring in a FUSI structure (especially an integrated gate electrode) having different metal contents is prevented or suppressed, and occurrence of an intermediate phase film due to metal diffusion is suppressed. As a result, the circuit area is reduced and variation in electrical characteristics is prevented.

### BRIEF DESCRIPTION OF THE DRAWINGS

FIGS. 1A and 1B illustrate a semiconductor device according to a first embodiment of the present invention. FIG. 1A is a plan view and FIG. 1B is a cross-sectional view taken along the line Ib-Ib in FIG. 1A.

FIG. 2 is a plan view illustrating a semiconductor device according to a first modified example of the first embodiment.

FIG. 3 is a plan view illustrating a semiconductor device according to a second modified example of the first embodiment.

FIG. 4 is a plan view illustrating a semiconductor device according to a third modified example of the first embodiment.

FIG. 5 is a cross-sectional view illustrating a semiconductor device according to a fourth modified example of the first embodiment.

FIG. 6 is a cross-sectional view illustrating a semiconductor device according to a fifth modified example of the first embodiment.

FIG. 7 is a cross-sectional view illustrating a semiconductor device according to a sixth modified example of the first embodiment.

FIGS. 8A through 8C illustrate a method for fabricating a semiconductor device according to the first embodiment. FIG. 8A is a plan view, FIG. 8B is a cross-sectional view taken along the line VIIIb-VIIIb in FIG. 8A, and FIG. 8C is a cross-sectional view taken along the line VIIIc-VIIIc in FIG. 8A.

FIGS. 9A through 9D illustrate the method for fabricating a semiconductor device according to the first embodiment. FIG. 9A is a plan view, FIG. 9B is a cross-sectional view taken along the line IXb-IXb in FIG. 9A, FIG. 9C is a cross-sectional view taken along the line IXc-IXc in FIG. 9A, and FIG. 9D is a cross-sectional view illustrating a modified example of FIG. 9C.

FIGS. 10A through 10D illustrate the method for fabricating a semiconductor device according to the first embodiment. FIG. 10A is a plan view, FIG. 10B is a cross-sectional view taken along the line Xb-Xb in FIG. 10A, FIG. 10C is a cross-sectional view taken along the line Xc-Xc in FIG. 10A, and FIG. 10D is a cross-sectional view illustrating a modified example of FIG. 10C.

FIGS. 11A through 11C illustrate the method for fabricating a semiconductor device according to the first embodiment. FIG. 11A is a plan view, FIG. 11B is a cross-sectional view taken along the line XIb-XIb in FIG. 11A, and FIG. 11C is a cross-sectional view taken along the line XIc-XIc in FIG. 11A.

FIGS. 12A through 12C illustrate the method for fabricating a semiconductor device according to the first embodiment. FIG. 12A is a plan view, FIG. 12B is a cross-sectional view taken along the line XIIb-XIIb in FIG. 12A, and FIG. 12C is a cross-sectional view taken along the line XIIc-XIIc in FIG. 12A.

FIGS. 13A through 13C illustrate the method for fabricating a semiconductor device according to the first embodiment. FIG. 13A is a plan view, FIG. 13B is a cross-sectional view taken along the line XIIIb-XIIIb in FIG. 13A, and FIG. 13C is a cross-sectional view taken along the line XIIIc-XIIIc in FIG. 13A.

FIGS. 14A through 14C illustrate the method for fabricating a semiconductor device according to the first embodiment. FIG. 14A is a plan view, FIG. 14B is a cross-sectional view taken along the line XIVb-XIVb in FIG. 14A, and FIG. 14C is a cross-sectional view taken along the line XIVc-XIVc in FIG. 14A.

FIGS. 15A through 15C illustrate the method for fabricating a semiconductor device according to the first embodiment. FIG. 15A is a plan view, FIG. 15B is a cross-sectional view taken along the line XVb-XVb in FIG. 15A, and FIG. 15C is a cross-sectional view taken along the line XVc-XVc in FIG. 15A.

FIGS. 16A and 16B illustrate a semiconductor device according to a second embodiment of the present invention. FIG. 16A is a plan view and FIG. 16B is a cross-sectional view taken along the line XVIb-XVIb in FIG. 16A.

FIG. 17 is a plan view illustrating a semiconductor device according to a first modified example of the second embodiment.

FIG. 18 is a cross-sectional view illustrating a semiconductor device according to a second modified example of the second embodiment.

FIGS. 19A through 19D illustrate a method for fabricating a semiconductor device according to the second embodiment. FIG. 19A is a plan view, FIG. 19B is a cross-sectional view taken along the line XIXb-XIXb in FIG. 19A, FIG. 19C is a cross-sectional view taken along the line XIXc-XIXc in FIG. 19A and FIG. 19D is a cross-sectional view illustrating a modified example of FIG. 19C.

FIGS. 20A through 20C illustrate the method for fabricating a semiconductor device according to the second embodiment. FIG. 20A is a plan view, FIG. 20B is a cross-sectional view taken along the line XXb-XXb in FIG. 20A, and FIG. 20C is a cross-sectional view taken along the line XXc-XXc in FIG. 20A.

FIGS. 21A through 21C illustrate the method for fabricating a semiconductor device according to the second embodiment. FIG. 21A is a plan view, FIG. 21B is a cross-sectional view taken along the line XXIb-XXIb in FIG. 21A, and FIG. 21C is a cross-sectional view taken along the line XXIc-XXIc in FIG. 21A.

FIGS. 22A through 22C illustrate the method for fabricating a semiconductor device according to the second embodiment. FIG. 22A is a plan view, FIG. 22B is a cross-sectional view taken along the line XXIIb-XXIIb in FIG. 22A, and FIG. 22C is a cross-sectional view taken along the line XXIIc-XXIIc in FIG. 22A.

FIGS. 23A through 23C illustrate the method for fabricating a semiconductor device according to the second embodiment. FIG. 23A is a plan view, FIG. 23B is a cross-sectional view taken along the line XXIIIb-XXIIIb in FIG. 23A, and FIG. 23C is a cross-sectional view taken along the line XXIIIc-XXIIIc in FIG. 23A.

FIGS. 24A through 24C illustrate the method for fabricating a semiconductor device according to the second embodiment. FIG. 24A is a plan view, FIG. 24B is a cross-sectional view taken along the line XXIVb-XXIVb in FIG. 24A, and FIG. 24C is a cross-sectional view taken along the line XXIVc-XXIVc in FIG. 24A.

FIGS. 25A through 25C illustrate the method for fabricating a semiconductor device according to the second embodiment. FIG. 25A is a plan view, FIG. 25B is a cross-sectional view taken along the line XXVb-XXVb in FIG. 25A, and FIG. 25C is a cross-sectional view taken along the line XXVc-XXVc in FIG. 25A.

FIGS. 26A and 26B illustrate a semiconductor device according to a third embodiment of the present invention. FIG. 26A is a plan view and FIG. 26B is a cross-sectional view taken along the line XXVIb-XXVIb in FIG. 26A.

FIG. 27 is a plan view illustrating a semiconductor device according to a modified example of the third embodiment.

FIGS. 28A through 28D illustrate a method for fabricating a semiconductor device according to the third embodiment. FIG. 28A is a plan view, FIG. 28B is a cross-sectional view taken along the line XXVIIIb-XXVIIIb in FIG. 28A, FIG. 28C is a cross-sectional view taken along the line XXVIIIc-XXVIIIc in FIG. 28A and FIG. 28D is a cross-sectional view illustrating a modified example of FIG. 28C.

FIGS. 29A through 29C illustrate the method for fabricating a semiconductor device according to the third embodiment. FIG. 29A is a plan view, FIG. 29B is a cross-sectional view taken along the line XXIXb-XXIXb in FIG. 29A, and FIG. 29C is a cross-sectional view taken along the line XXIXc-XXIXc in FIG. 29A.

FIGS. 30A through 30C illustrate the method for fabricating a semiconductor device according to the third embodiment. FIG. 30A is a plan view, FIG. 30B is a cross-sectional view taken along the line XXXb-XXXb in FIG. 30A, and FIG. 30C is a cross-sectional view taken along the line XXXc-XXXc in FIG. 30A.

FIGS. 31A through 31C illustrate the method for fabricating a semiconductor device according to the third embodiment. FIG. 31A is a plan view, FIG. 31B is a cross-sectional view taken along the line XXXIb-XXXIb in FIG. 31A, and FIG. 31C is a cross-sectional view taken along the line XXXIc-XXXIc in FIG. 31A.

FIGS. 32A through 32C illustrate the method for fabricating a semiconductor device according to the third embodiment. FIG. 32A is a plan view, FIG. 32B is a cross-sectional view taken along the line XXXIIb-XXXIIb in FIG. 32A, and FIG. 32C is a cross-sectional view taken along the line XXXIIc-XXXIIc in FIG. 32A.

FIGS. 33A through 33C illustrate the method for fabricating a semiconductor device according to the third embodiment. FIG. 33A is a plan view, FIG. 33B is a cross-sectional view taken along the line XXXIIIb-XXXIIIb in FIG. 33A, and FIG. 33C is a cross-sectional view taken along the line XXXIIIc-XXXIIIc in FIG. 33A.

FIGS. 34A through 34D are cross-sectional view illustrating respective process steps for forming conventional FETs having FUSI structures in the order of fabrication.

FIG. 35 is a plan view illustrating conventional FETs having a FUSI common gate electrode.

FIG. 36 is a cross-sectional view showing problems in conventional FETs having a FUSI common gate electrode.

### DETAILED DESCRIPTION OF THE INVENTION

### Embodiment 1

A first embodiment of the present invention will be described with reference to the drawings.

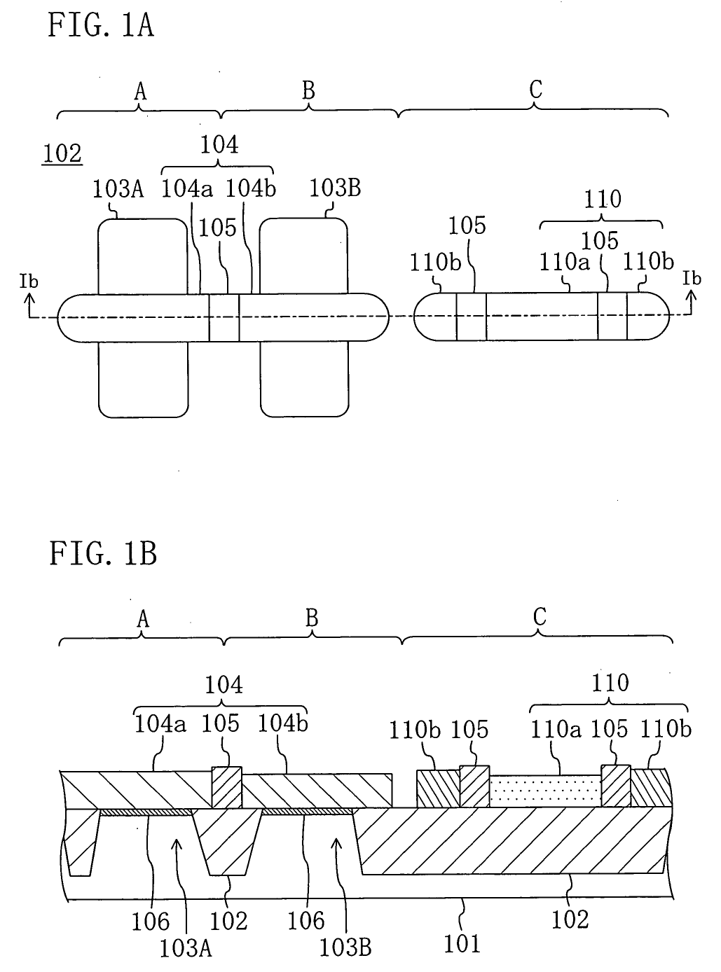

FIGS. 1A and 1B illustrate a semiconductor device according to the first embodiment. FIG. 1A is a plan view and FIG. 1B is a cross-sectional view taken along the line Ib-Ib in FIG. 1A. As illustrated in FIGS. 1A and 1B, the principal surface of a semiconductor substrate 101 made of, for example, silicon is partitioned into an n-FET region A, a p-FET region B and a resistor region C by an isolation region 102 of shallow trench isolation (STI).

An n-type active region 103A and a p-type active region 103B are formed in the respective n- and p-FET regions A and B. The n-type active region 103A and the p-type active region 103B are spaced out with their long sides (of rectangles) facing each other in plan view. A common gate electrode 104 is formed over the n-type active region 103A and the p-type active region 103B with a gate insulating film 106 of, for example, hafnium oxide (HfO₂) interposed therebetween. The common gate electrode 104 extends across both long sides of each of the active regions 103A and 103B. The gate insulating film 106 is not necessarily made of HfO₂ and may be made of HfSiO, HfSiON, SiO₂ or SiON, for example.

The common gate electrode 104 includes a first gate electrode 104a made of NiSi in the n-FET region A and a second gate electrode 104b made of Ni₃Si in the p-FET region B. In a portion of the common gate electrode 104 located on the isolation region 102 and connecting the first gate electrode 104a and the second gate electrode 104b, a diffusion preventing film 105 made of WSi and used for preventing diffusion of nickel (Ni) in this portion is formed.

A resistor 110 including: a resistor body 110a of polysilicon; a contact region 110b made of NiSi and located at an end of the resistor body 110a; and a diffusion preventing film 105 made of WSi and located in a portion connecting the resistor body 110a and the contact region 110b is formed on the isolation region 102 in the resistor region C.

In the first embodiment, the diffusion preventing film 105 covers the entire surface of the connecting portion (i.e., interface) between the first gate electrode 104a and the second gate electrode 104b and has a width (i.e., gate length) equal to that of the common gate electrode 104 in the n-FET region A and the p-FET region B. In the resistor region C, the diffusion preventing film 105 also covers the entire surface of the connecting portion (i.e., interface) between the resistor body 110a and the contact region 110b and has a width equal to that of the resistor body 110a and the contact region 110b.

Hereinafter, modified examples of the first embodiment will be described.

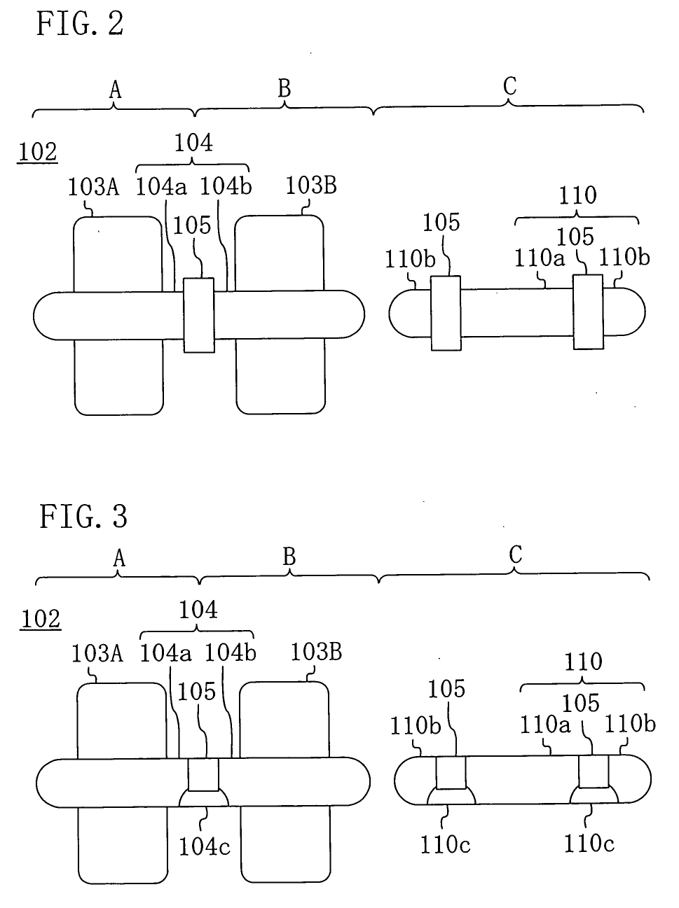

FIGS. 2, 3 and 4 are plan views illustrating structures similar to that illustrated in FIG. 1A.

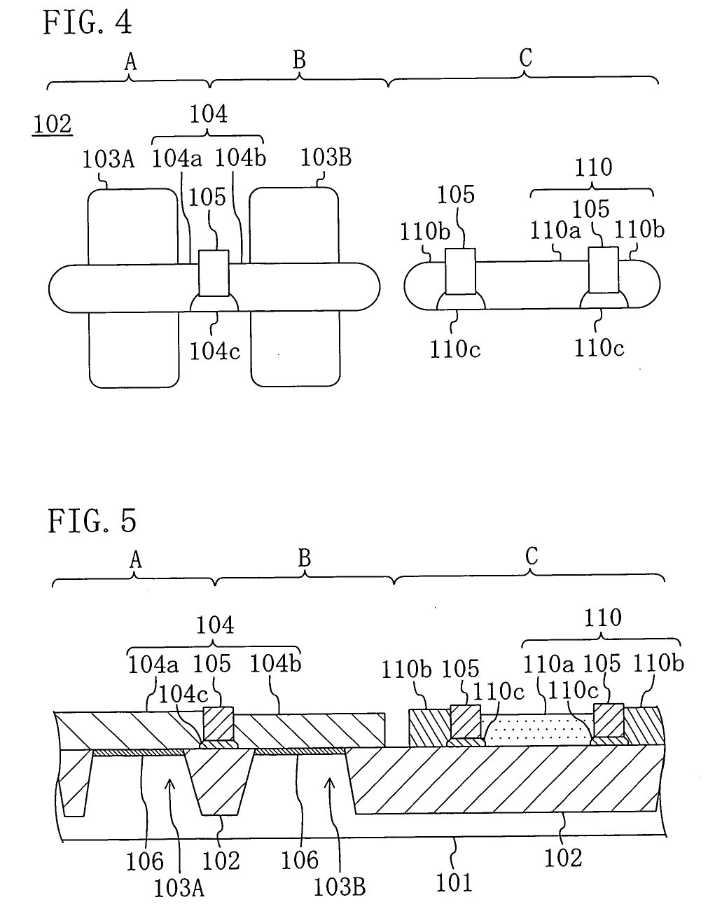

In a first modified example illustrated in FIG. 2, the diffusion preventing films 105 are wider than the common gate electrode 104 and the resistor 110. In a second modified example illustrated in FIG. 3, though the diffusion preventing films 105 do not project in the width direction, one side of each of the connecting portions is not covered with the diffusion preventing films 105. Accordingly, intermediate phase films 104c and 110c each having a metal content different from a predetermined metal content is formed on the uncovered sides of the connecting portions. In a third modified example illustrated in FIG. 4, the diffusion preventing films 105 project in the width direction and one side of each of the connecting portions is not covered with the diffusion preventing film 105.

FIGS. 5, 6 and 7 are cross-sectional views illustrating structures similar to that of FIG. 1B.

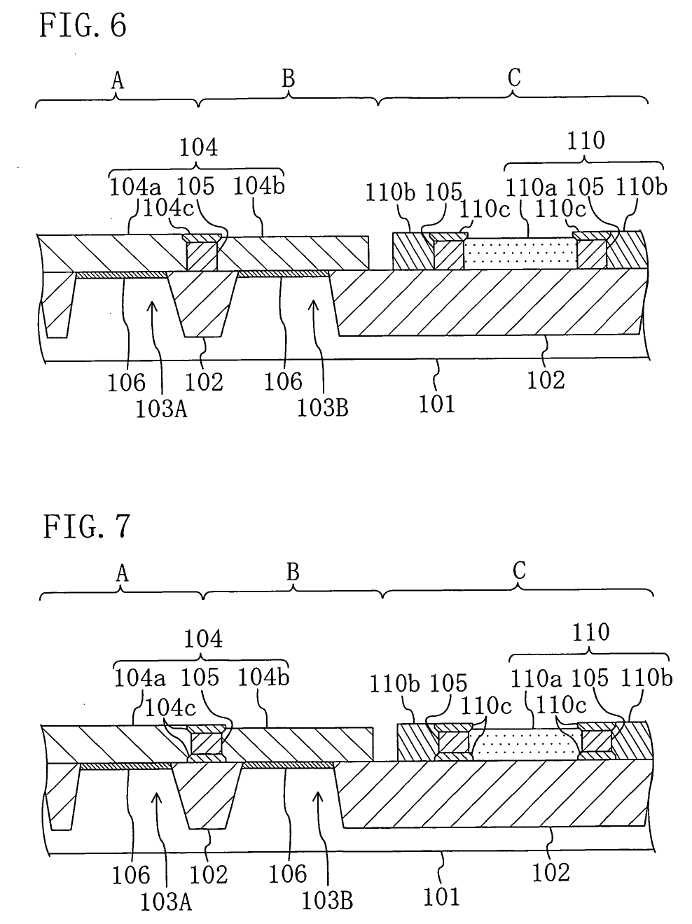

In a fourth modified example illustrated in FIG. 5, the lower end of each of the connecting portions is not covered with the diffusion preventing film 105. Accordingly, intermediate phase films 104c and 110c each having a metal content different from a predetermined metal content are formed in the lower ends of the connecting portions. In a fifth modified example illustrated in FIG. 6, the upper end of each of the connecting portions is not covered with the diffusion preventing film 105. Accordingly, intermediate phase films 104c and 110c each having a metal content different from a predetermined metal content are formed in the upper ends of the connecting portions. In a sixth modified example illustrated in FIG. 7, the upper and lower ends of each of the connecting portions are not covered with the diffusion preventing film 105. Accordingly, intermediate phase films 104c and 110c each having a metal content different from a predetermined metal content are formed in the upper and lower ends of the connecting portions.

In the second through sixth modified examples, the entire surfaces of the connecting portions are not covered with the diffusion preventing films 105, and the intermediate phase films 104c and 110c are formed accordingly. However, as illustrated in FIG. 3, for example, the intermediate phase film 104c formed in the connecting portion of the common gate electrode 104 does not reach the upper portions of the respective active regions 103A and 103B across the isolation region 102, unlike the conventional example illustrated in FIG. 36. Accordingly, the threshold voltages of the FETs do not vary. The same holds for the resistor 110, so that the resistance value of the resistor body 110a does not change greatly.

In this manner, in the semiconductor devices of the first embodiment and the modified examples thereof, the diffusion preventing film 105 used for preventing diffusion of metal (nickel) and made of a conductive material which is not silicided is provided in a portion connecting the first gate electrode 104a and the second gate electrode 104b, thereby preventing metal diffusion while suppressing increase of the electrical resistance of the common gate electrode 104. Accordingly, variation of the threshold voltages of the FETs and variation of the resistance of the resistor 110 are prevented with the circuit area reduced. As a result, the performance of the semiconductor device is enhanced and the integration degree thereof is allowed to be increased.

In the first embodiment, WSi is used as a conductive material of the diffusion preventing film 105. However, this conductive material only needs to be a metal or a metal compound which does not react with silicon in a silicidation process in which the first gate electrode 104a, the second gate electrode 104b and the contact regions 110b are silicided. For example, CoSi₂, TiN or WN may be used. The diffusion preventing film 105 is not limited to a single-layer film and may be a multilayer film made of TiN and WSi, for example.

The entire connecting portion between the first gate electrode 104a and the second gate electrode 104b is preferably covered with the conductive diffusion preventing film 105 as illustrated in FIGS. 1A and 1B and FIG. 2, for example, because the effect of preventing metal diffusion is at the maximum in this structure. However, as in the modified examples illustrated in FIGS. 3 through 7, the diffusion preventing film 105 may be formed as a part of each connecting portion. In such cases, the cross-sectional area where metal is diffused is also reduced so that metal diffusion is suppressed and the amount of the intermediate phase films 104c and 110c is reduced. Accordingly, formation of the intermediate phase films 104c and 110c is limited within a small area. As a result, the circuit area is reduced and variation in electrical characteristics is suppressed in the modified examples, as described above.

In addition, in a structure in which the cross-sectional area of the diffusion preventing film 105 is partially larger than that of a portion of the connection portion between the first gate electrode 104a and the second gate electrode 104b, even when the specific resistance of the diffusion preventing film 105 is higher than those of the first gate electrode 104a and the second gate electrode 104b, increase of the resistance value caused by the diffusion preventing film 105 is suppressed. The same holds for the resistor 110.

Hereinafter, a method for fabricating a semiconductor device with the above configuration will be described with reference to the drawings.

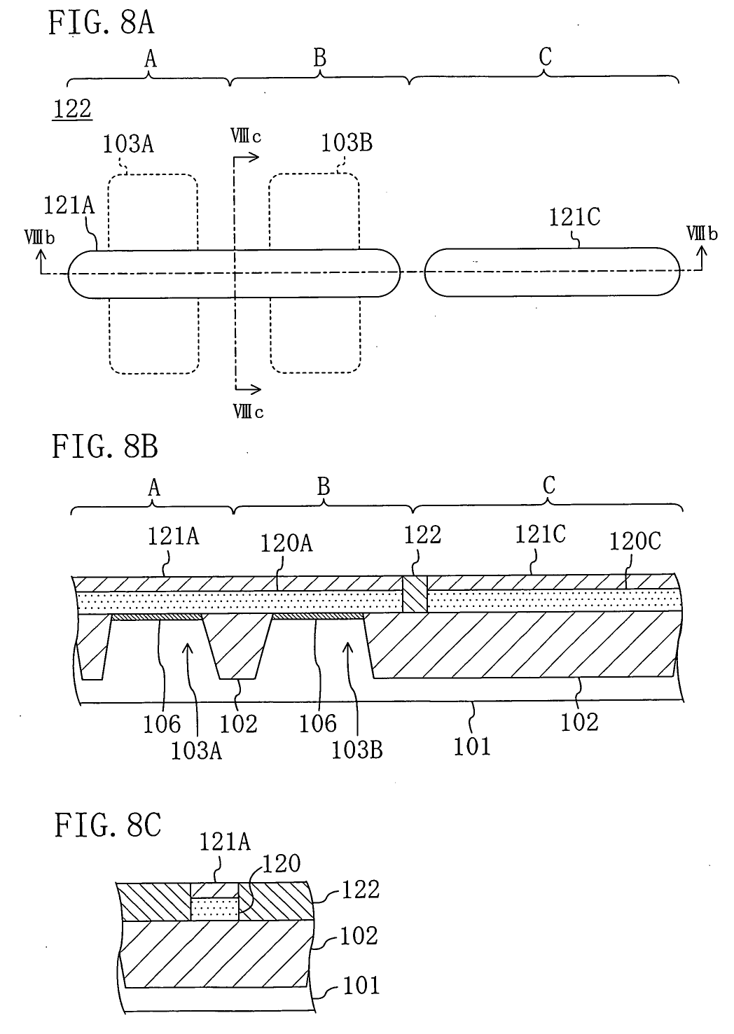

FIGS. 8A through 8C to FIGS. 15A through 15C are plan views and cross-sectional views showing structures in respective process steps of a method for fabricating a semiconductor device according to the first embodiment in the order of fabrication.

First, as shown in FIGS. 8A through 8C, an isolation region 102 of STI is selectively formed in an upper portion of a semiconductor substrate 101 made of silicon. In this manner, an n-type active region 103A and a p-type active region 103B are defined in an n-FET region A and a p-FET region B, respectively. Subsequently, though not shown, a p-well region and a p-type threshold-value-control doped region are formed in the n-type active region 103A by ion implantation of p-type impurity ions, whereas an n-well region and an n-type threshold-value-control doped region are formed in the p-type active region 103B by ion implantation of n-type impurity ions. Thereafter, a gate insulating film 106 of hafnium oxide (HfO₂) is deposited by chemical vapor deposition (CVD) to a physical thickness of 3 nm over the n-type active region 103A and the p-type active region 103B in the semiconductor substrate 101. Thereafter, a polysilicon film is deposited by CVD to a thickness of 75 nm over the entire surface of the semiconductor substrate 101 including the isolation region 102 and the gate insulating film 106. Then, a resist film having an opening pattern only in a resistor region C is formed on the polysilicon film. Thereafter, impurity implantation for determining the resistance value of a resistor is performed on a region to be a silicon resistor 120C, using the resist film as a mask. Subsequently, the resist film is removed, and then a silicon dioxide (SiO₂) film is deposited to a thickness of 25 nm over the polysilicon film. Thereafter, etching is sequentially performed on the silicon dioxide film and the polysilicon film by lithography and etching, thereby forming a first protective insulating film 121A of silicon dioxide and a first silicon gate electrode 120A of polysilicon in the n-FET region A and the p-FET region B. The first protective insulating film 121A and the first silicon gate electrode 120A have a common gate electrode pattern. At the same time, a second protective insulating film 121C of silicon dioxide and a silicon resistor 120C of polysilicon are formed in the resistor region C. The second protective insulating film 121C and the silicon resistor 120C have a resistor pattern. If dry etching is used as etching in this process, a gas containing fluorocarbon as a main component is used as an etching gas for silicon dioxide and a gas containing chlorine as a main component is used as an etching gas for polysilicon. Thereafter, though not shown, an n-type extension region may be formed in the n-type active region 103A using the first protective insulating film 121A as a mask and a p-type extension region may be formed in the p-type active region 103B using the first protective insulating film 121A as a mask. Subsequently, sidewall spacers of, for example, silicon nitride are formed on both sides of each of the first protective insulating film 121A and the first silicon gate electrode 120A. Using the sidewall spacers and the first protective insulating film 121A as masks, n-type source/drain regions are formed in the n-type active region 103A and p-type source/drain regions are formed in the p-type active region 103B. Subsequently, a third protective insulating film 122 of silicon oxide is deposited by CVD over the entire surface of the semiconductor substrate 101 including the isolation region 102, the first protective insulating film 121A and the second protective insulating film 121C. Then, the third protective insulating film 122 is planarized by, for example, chemical mechanical polishing (CMP), thereby exposing the first protective insulating film 121A and the second protective insulating film 121C.

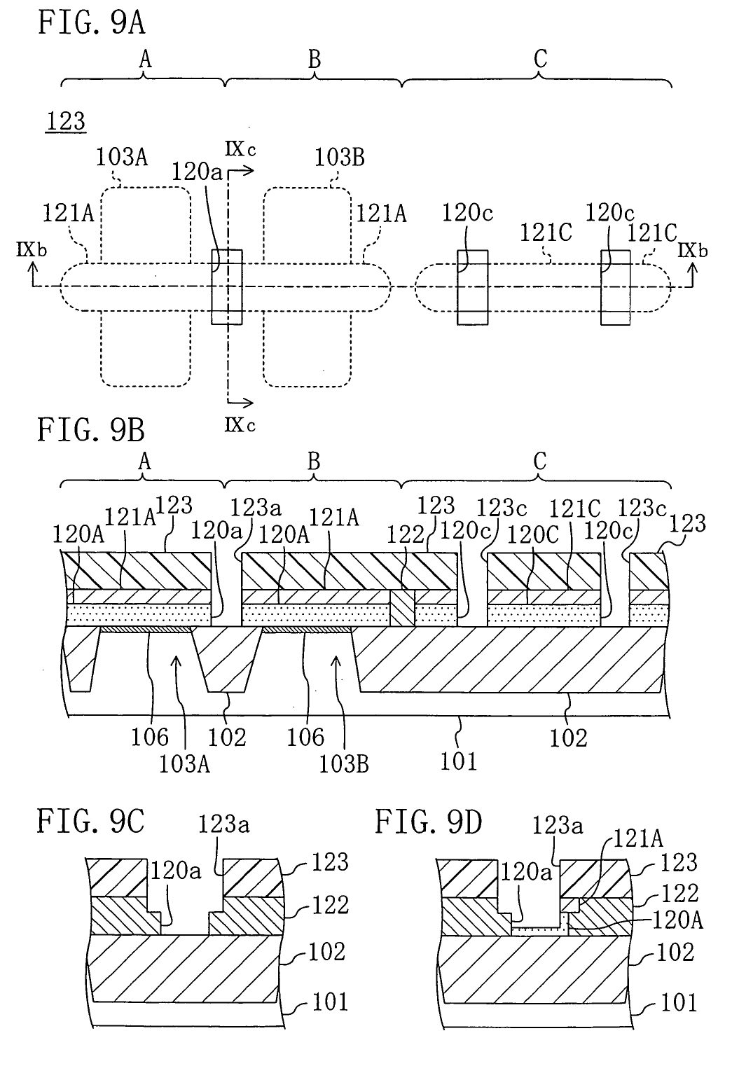

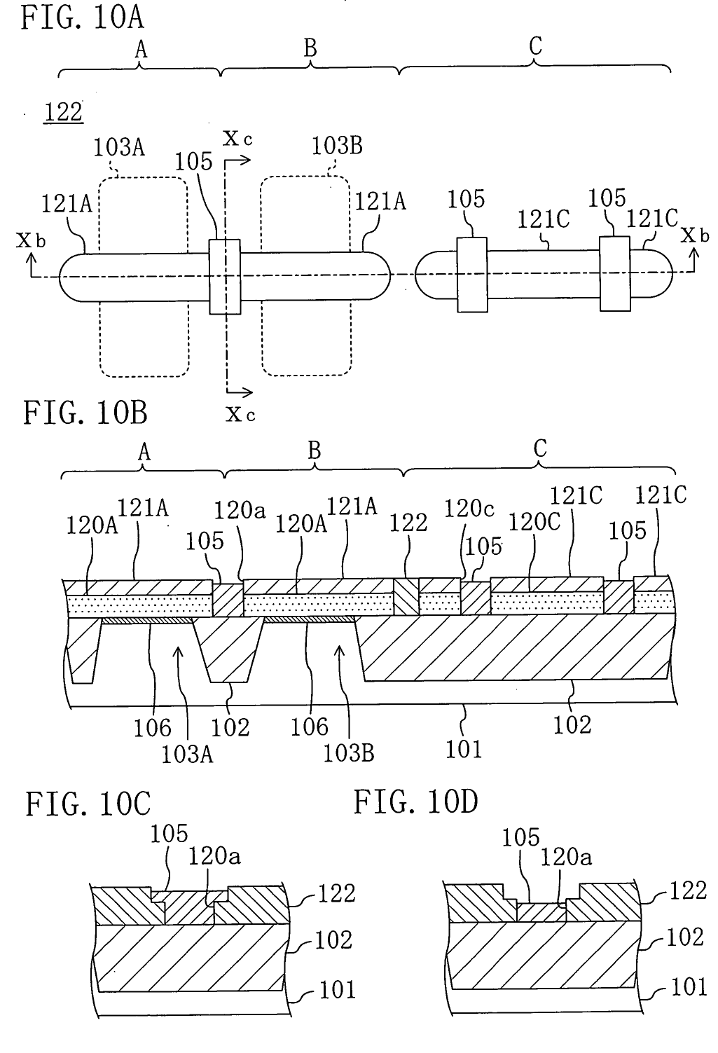

Next, as shown in FIGS. 9A through 9D, a first resist film 123 is applied by lithography onto the third protective insulating film 122 including the exposed first and second protective insulating films 121A and 121C. A first opening pattern 123a in which the connection portion between the n-FET region A and the p-FET region B in the first silicon gate electrode 120A in the first resist film 123 is exposed and second opening patterns 123c in each of which the connection portion between the resistor body and a contact region in the silicon resistor 120C is exposed are formed. Subsequently, using the first resist film 123 having the opening patterns 123a and 123c as a mask, anisotropic etching is sequentially performed on the first and second protective insulating films 121A and 121C, the first silicon gate electrode 120A and the silicon resistor 120C, thereby forming a first opening 120a in the connection portion of the first silicon gate electrode 120A and second openings 120c in the silicon resistor 120C. At this time, it is preferable that the first silicon gate electrode 120A and the silicon resistor 120C are completely removed from the first opening 120a and the second openings 120c. However, as illustrated in FIG. 9D, polysilicon may be left on the sides and/or bottoms of the openings. In this embodiment, as illustrated in FIGS. 9A and 9C, to easily form the first opening 120a, the opening in the first protective insulating film 121A is wider than that in the underlying silicon resistor 120C. The same holds for the second openings 120c. The shape of each of the openings 120a and 120c is a rectangle in plan view. However, as will be described with reference to FIG. 10D, if the upper surface of a diffusion preventing film 105 is lower than those of the first silicon gate electrode 120A and the silicon resistor 120C, the shape of an upper portion of each of the openings 120a and 120c may be a trench in plan view with which patterning is easily performed. This is because of the following reasons. In a case where a plurality of FETs are formed to be adjacent to one another, if a trench is formed in an upper portion of the first opening 120a and a diffusion preventing film 105 made of a conductor is thicker than the first silicon gate electrode 120A, for example, the trench is filled with the conductive diffusion preventing film 105 so that a short circuit occur between adjacent gate electrodes. However, if the diffusion preventing film 105 is thinner than the first silicon gate electrode 120A, the diffusion preventing film 105 is formed to be separated from each other on the bottoms of the respective openings 120a and 120c which are in the shapes of rectangles in plan view so that the possibility of a short-circuit is eliminated. In addition, in consideration of misalignment, the openings 120a and 120c are preferably formed such that the short sides of the openings 120a and 120c do not overlap with the first silicon gate electrode 120A and the silicon resistor 120C. However, even if these short sides overlap with the first silicon gate electrode 120A and the silicon resistor 120C, no substantial problems occur as shown in FIGS. 3 and 4.

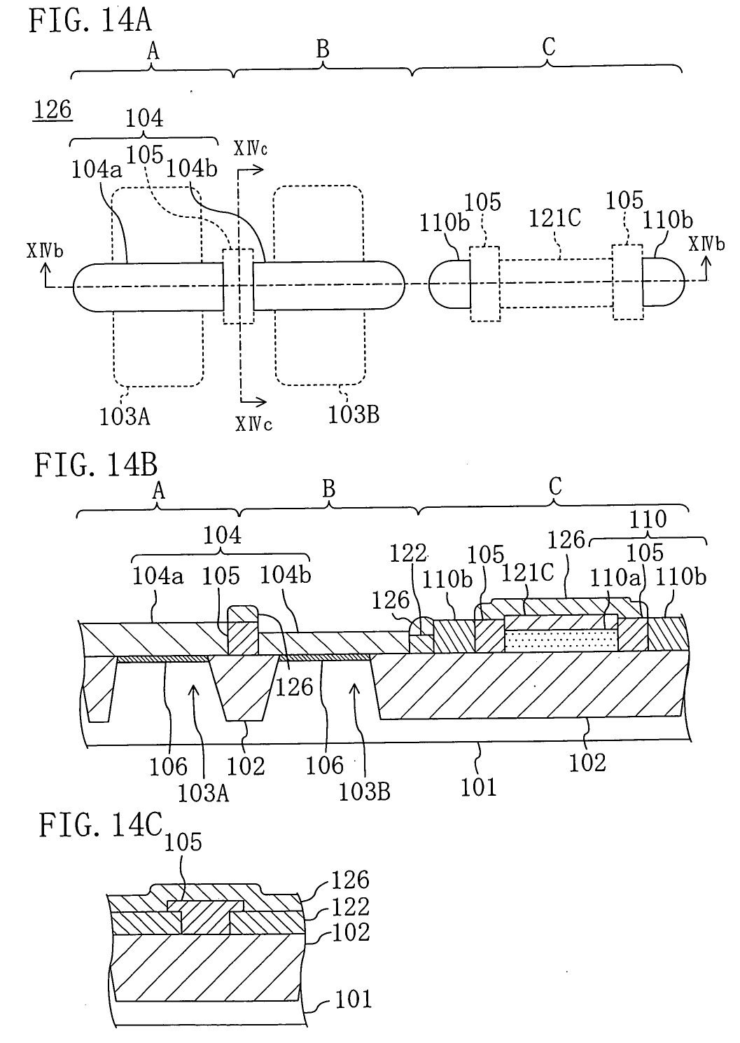

Thereafter, as shown in FIGS. 10A through 10D, the first resist film 123 is removed, and then a WSi film is deposited by, for example, CVD over the third protective insulating film 122 to fill the first opening 120a and the second openings 120c. Subsequently, the WSi film is etched back, for example, so that a portion of the WSi film located on the third protective insulating film 122 is removed, thereby forming a diffusion preventing films 105 of WSi in each of the first opening 120a in the first silicon gate electrode 120A and the second openings 120c in the silicon resistor 120C. At this time, the thickness of the diffusion preventing films 105 remaining in the openings 120a and 120c are preferably substantially equal to that of a first gate electrode 104a or a second gate electrode 104b which will be formed by a silicide process shown in FIG. 14B. However, the upper surface of each of the diffusion preventing films 105 may be at a midpoint between the top and bottom of the first protective insulating film 121A or the second protective insulating film 121C or may be at a midpoint between the top and bottom of the first silicon gate electrode 120A or the silicon resistor 120C as long as the diffusion preventing films 105 cause no short circuit between adjacent gate electrodes. Accordingly, as shown in FIG. 10D, to make the diffusion preventing films 105 remaining in the openings 120a and 120c thinner than the first silicon gate electrode 120A, an upper portion of each of the openings 120a and 120c may be formed in the shape of a trench. The upper portions of the openings 120a and 120c herein are portions corresponding to the first protective insulating film 121A and the second protective insulating film 121C. In the first embodiment, the openings 120a and 120c are filled with the diffusion preventing films 105. However, voids may be partially formed in the diffusion preventing films 105. Even in such a case, no substantial problems occur.

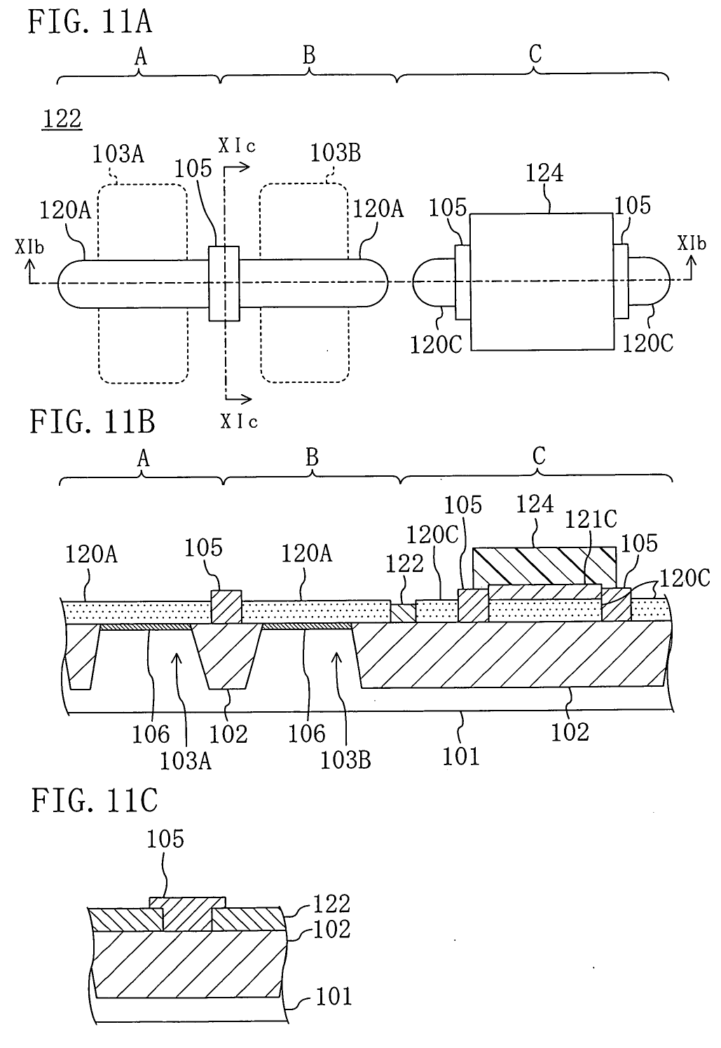

Subsequently, as shown in FIGS. 11A through 11C, a second resist film 124 covering a portion of the silicon resistor 120C sandwiched between two diffusion preventing films 105 is formed on the second protective insulating film 121C by lithography. Using the second resist film 124 as a mask, both ends (i.e., contact regions) of each of the first protective insulating film 121A and the second protective insulating film 121C are removed by wet etching using hydrofluoric acid, for example.

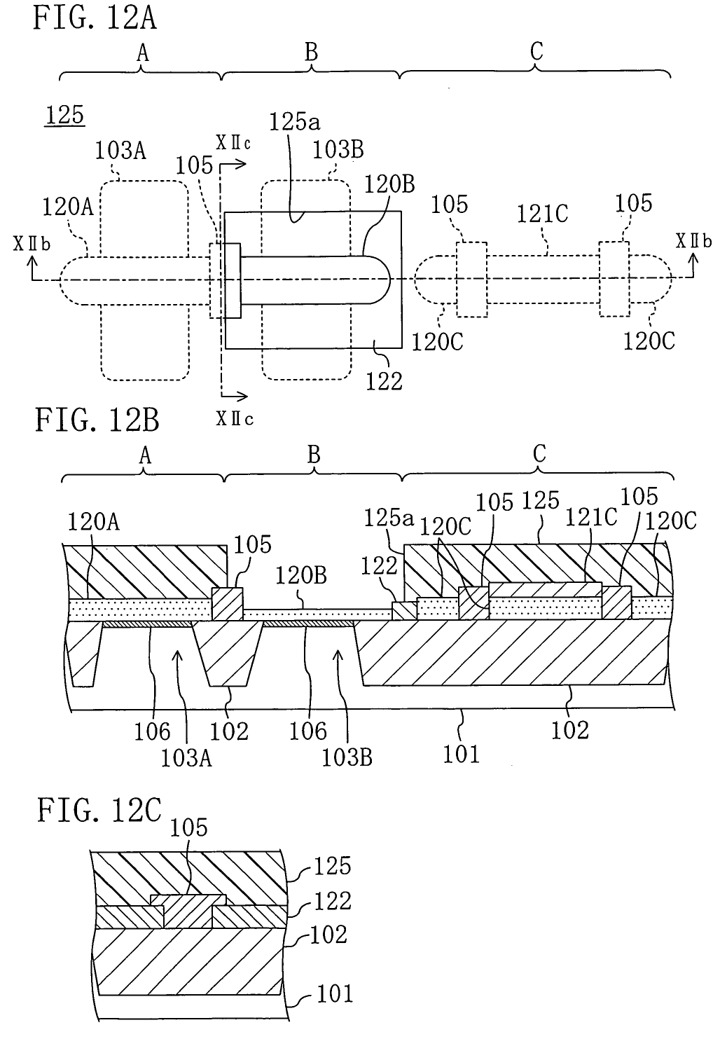

Then, as shown in FIGS. 12A through 12C, the second resist film 124 is removed, and then a third resist film 125 having an opening pattern 125a in which the p-FET region B is exposed is formed on the third protective insulating film 122 by lithography. Subsequently, using the third resist film 125 as a mask, dry etching using a chlorine gas as a main component is performed on the first silicon gate electrode 120A in the p-FET region B, thereby obtaining a second silicon gate electrode 120B with a thickness of 25 nm out of the first silicon gate electrode 120A.

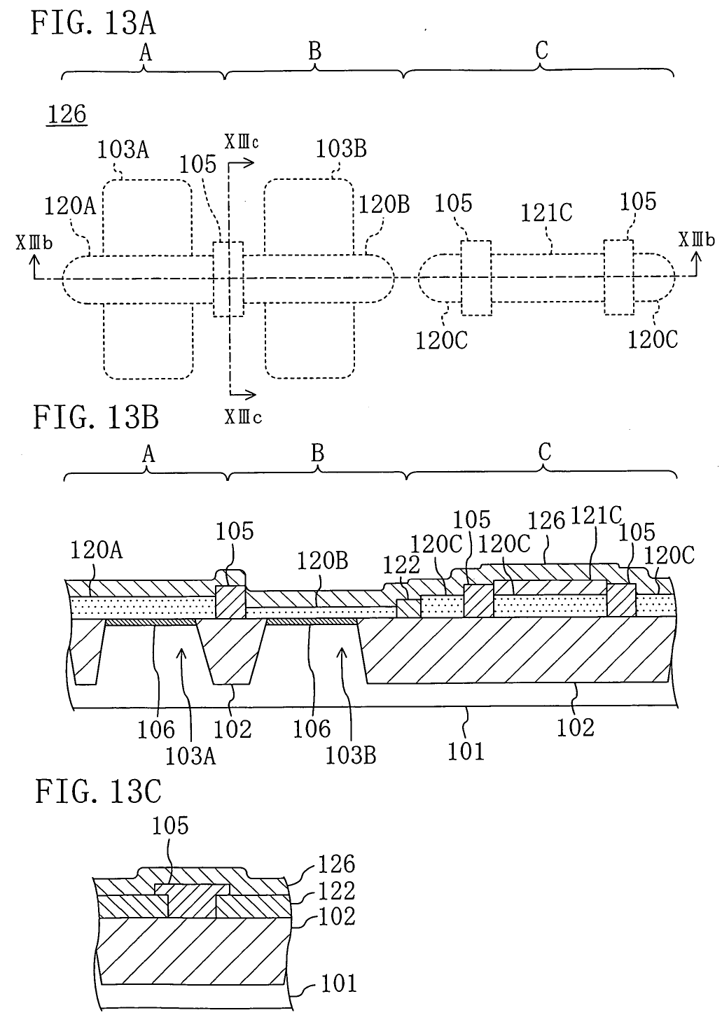

Thereafter, as shown in FIGS. 13A through 13C, the third resist film 125 is removed. Then, a metal film 126 of nickel (Ni) is deposited by, for example, sputtering to a thickness of 35 nm over the entire surface of the third protective insulating film 122 including the first silicon gate electrode 120A, the second silicon gate electrode 120B, the silicon resistor 120C partially to be contact regions, and the second protective insulating film 121C.

Subsequently, as shown in FIGS. 14A through 14C, heat treatment is performed on the semiconductor substrate 101 at 400° C. in a nitrogen atmosphere by, for example, rapid thermal annealing (RTA), thereby causing silicidation between the metal film 126 and each of the first silicon gate electrode 120A, the second silicon gate electrode 120B and the silicon resistor 120C. As a result, these polysilicon parts are fully silicided. Specifically, the first silicon gate electrode 120A is changed to a fully-silicided (FUSI) first gate electrode 104a made of NiSi and the second silicon gate electrode 120B is changed to a FUSI second gate electrode 104b made of Ni₃Si. This is because the second silicon gate electrode 120B is thinner than the first silicon gate electrode 120A so that the second silicon gate electrode 120B is silicided to be silicon-rich to a greater extent than the first silicon gate electrode 120A. In the resistor region C, portions of the silicon resistor 120C located outside the diffusion preventing films 105 are changed to contact regions 110b made of NiSi. A portion of the silicon resistor 120C located inside the diffusion preventing films 105 is covered with the second protective insulating film 121C, so that no silicidation occurs, and this portion is changed to a resistor body 110a of polysilicon. At this time, since the diffusion preventing films 105 made of a conductive material and preventing diffusion of metal (nickel) are provided in the connecting portion between the first gate electrode 104a and the second gate electrode 104b and the connecting portions between the resistor body 110a and the contact regions 110b, formation of intermediate phase films having metal contents different from predetermined metal contents is prevented. As shown in FIG. 9D, if polysilicon remains in the first opening 120a, the remaining polysilicon forms an intermediate phase film, but the amount of this film is very small. If the diffusion preventing films 105 are thinner than the polysilicon films such as the first silicon gate electrode 120A in the first opening 120a and the second openings 120c as shown in FIG. 10D, intermediate phase films can also be formed on the diffusion preventing films 105. However, in such a case, the amount of these intermediate phase films is very small, so that the intermediate phase films enter the first gate electrode 104a, the second gate electrode 104b and the resistor body 110a to small extents.

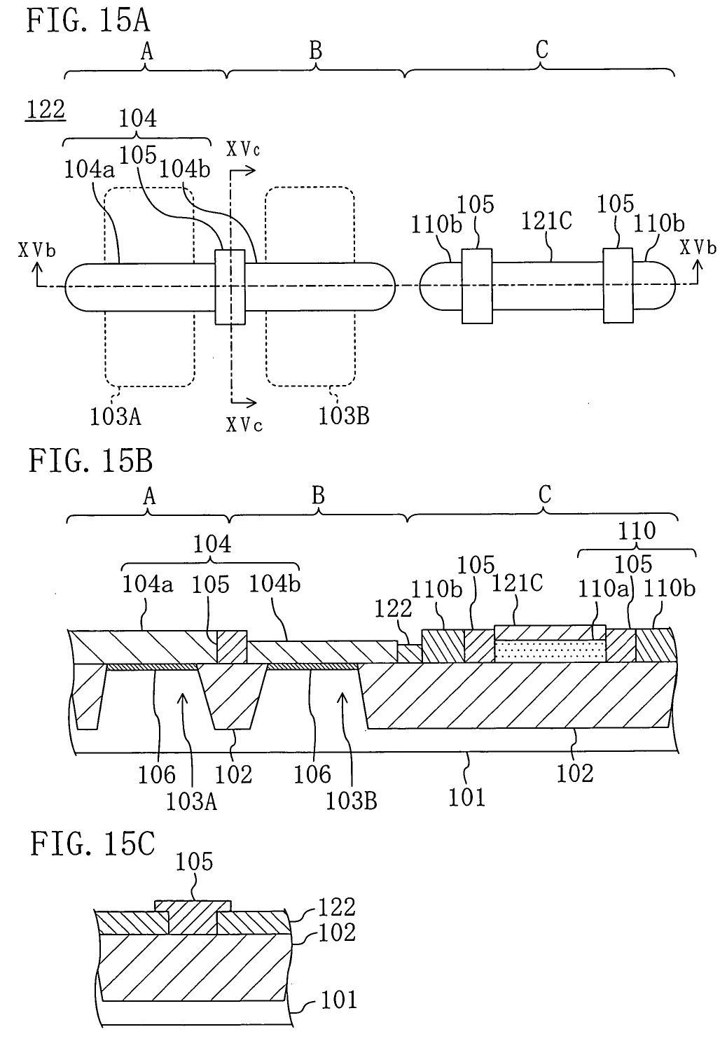

Subsequently, as shown in FIGS. 15A through 15C, the unreacted portion of the metal film 126 is etched and removed with, for example, a solution in which sulfuric acid and a hydrogen peroxide solution are mixed. Thereafter, though not shown, an interlayer insulating film is deposited over the entire surfaces of the n-FET region A, the p-FET region B and the resistor region C, and contact holes and interconnections are formed by known methods.

In this manner, with the method for fabricating a semiconductor device according to the first embodiment, the conductive diffusion preventing films 105 for preventing metal diffusion are at least partially formed in the connecting portion between the first gate electrode 104a and the second gate electrode 104b in the n-FET region A and the p-FET region B and in the connecting portions between the resistor body 110a and the contact regions 110b in the resistor region C. Accordingly, formation of intermediate phase films in the connecting portions due to diffusion of metal for silicidation is prevented.

In addition, an n-FET and a p-FET having a FUSI common gate electrode 104 and a resistor 110 having the FUSI contact regions 110b are formed at a time.

As shown in FIGS. 9A through 9D, the first opening 120a and the second openings 120c are formed in the first silicon gate electrode 120A and the silicon resistor 120C, respectively, with the first protective insulating film 121A and the second protective insulating film 121C being formed. Alternatively, as shown in FIGS. 12A through 12C, the openings 120a and 120c may be formed after the thickness of the first silicon gate electrode 120A in the p-FET region B is reduced to form the second silicon gate electrode 120B.

The first protective insulating film 121A and the second protective insulating film 121C are not necessarily formed. For example, in the processes shown in FIGS. 9A through 9D to FIGS. 12A through 12C, the processes may be performed with the first silicon gate electrode 120A and the silicon resistor 120C exposed using the resist films 123, 124 and 125 and not using the protective insulating films 121A and 121C.

In the resistor region C, if a portion of the metal film 126 located on a region (i.e., the resistor body 110a) of the silicon resistor 120C sandwiched between the diffusion preventing films 105 is removed after the process step shown in FIGS. 13A through 13C, the second protective insulating film 121C and the second resist film 124 are unnecessary.

### Embodiment 2

Hereinafter, a second embodiment of the present invention will be described with reference to the drawings.

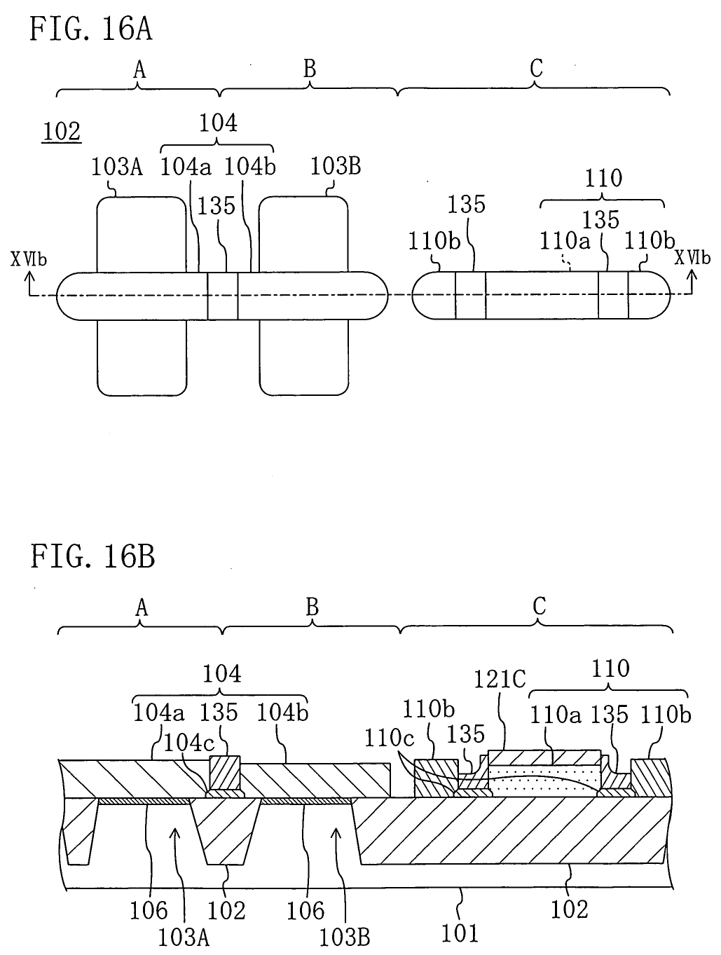

FIGS. 16A and 16B illustrate a semiconductor device according to the second embodiment. FIG. 16A is a plan view and FIG. 16B is a cross-sectional view taken along the line XVIb-XVIb in FIG. 16A. In FIGS. 16A and 16B, components also shown in FIGS. 1A and 1B are denoted by the same reference numerals, and description thereof will be omitted.

As illustrated in FIGS. 16A and 16B, the second embodiment is different from the first embodiment in that an insulating material is used for diffusion preventing films 135. In this manner, if the diffusion preventing films 135 are made of silicon dioxide (SiO₂), for example, increase in number of process steps is suppressed, as compared to cases of using other materials.

In addition, as illustrated in FIG. 16B, in the second embodiment, the diffusion preventing films 135 are made of an insulating material, so that an intermediate phase film 104c having a metal content between a first gate electrode 104a of NiSi and a second gate electrode 104b of Ni₃Si is formed under the diffusion preventing film 135 in a common gate electrode 104, whereas intermediate phase films 110c having a metal content between contact regions 110b of NiSi and a resistor body 110a of polysilicon are formed under the diffusion preventing films 135 in a resistor region C.

The intermediate phase films 104c and 110c are not limited to a material formed by mutual diffusion of metal for silicidation between the first gate electrode 104a and the second gate electrode 104b. Alternatively, a conductive material, e.g., WSi, CoSi₂, TiN or WN may be used.

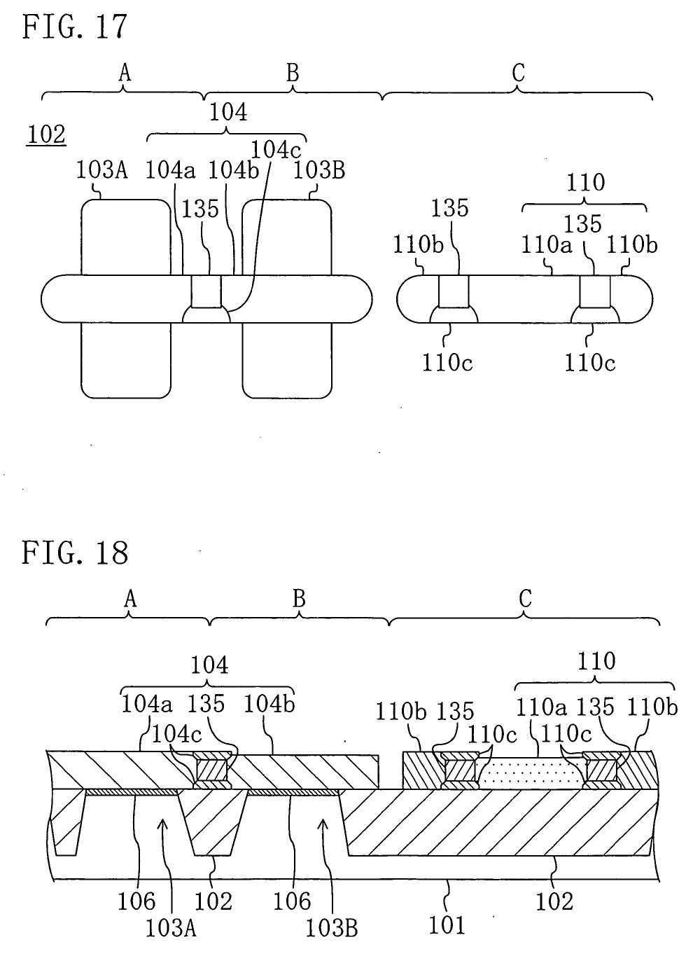

In a first modified example illustrated in FIG. 17, the intermediate phase films 104c and 110c are not necessarily formed under the diffusion preventing films 135 and may be formed on the sides of the diffusion preventing films 135.

In a second modified example illustrated in FIG. 18, the intermediate phase films 104c and 110c may also be formed on top of the diffusion preventing films 105. In either case, the insulating diffusion preventing films 135 reduce the cross-sectional area of the connecting portions in which metal diffusion occurs, so that the amount of the intermediate phase films 104c and 110c is suppressed.

It should be noted that the cross-sectional areas of the diffusion preventing films 135 are preferably larger than those of the intermediate phase films 104c and 110c in the direction vertical to the substrate in the second embodiment.

In this manner, in the semiconductor device of the second embodiment, the insulating diffusion preventing films 135 for preventing metal diffusion are partially formed in the connecting portion between the first gate electrode 104a and the second gate electrode 104b in the common gate electrode 104 in an n-FET region A and a p-FET region B and in the connecting portions between a resistor body 110a and contact regions 110b in the resistor region C, so that diffusion of metal for silicidation is suppressed. Accordingly, the threshold voltages of FETs and the resistance value of a resistor 110 vary in small circuit areas.

In addition, the conductive intermediate phase films 104c and 110c remain in the other part of the connecting portion between the first gate electrode 104a and the second gate electrode 104b in the common gate electrode 104 and in the other part of the connecting portions between the resistor body 110a and the contact regions 110b in the resistor 110. Accordingly, even if the insulating material is used for the diffusion preventing films 135, electrical connection is maintained in the common gate electrode 104 and the resistor 110. As a result, the performance of the semiconductor device is enhanced and the integration degree thereof is increased.

In the second embodiment, silicon dioxide is used for the diffusion preventing films 135. Alternatively, other insulating materials may be used as long as metal diffusion is prevented. For example, silicon nitride (Si₃N₄) may be used.

Hereinafter, a method for fabricating a semiconductor device having the foregoing structure will be described with reference to the drawings.

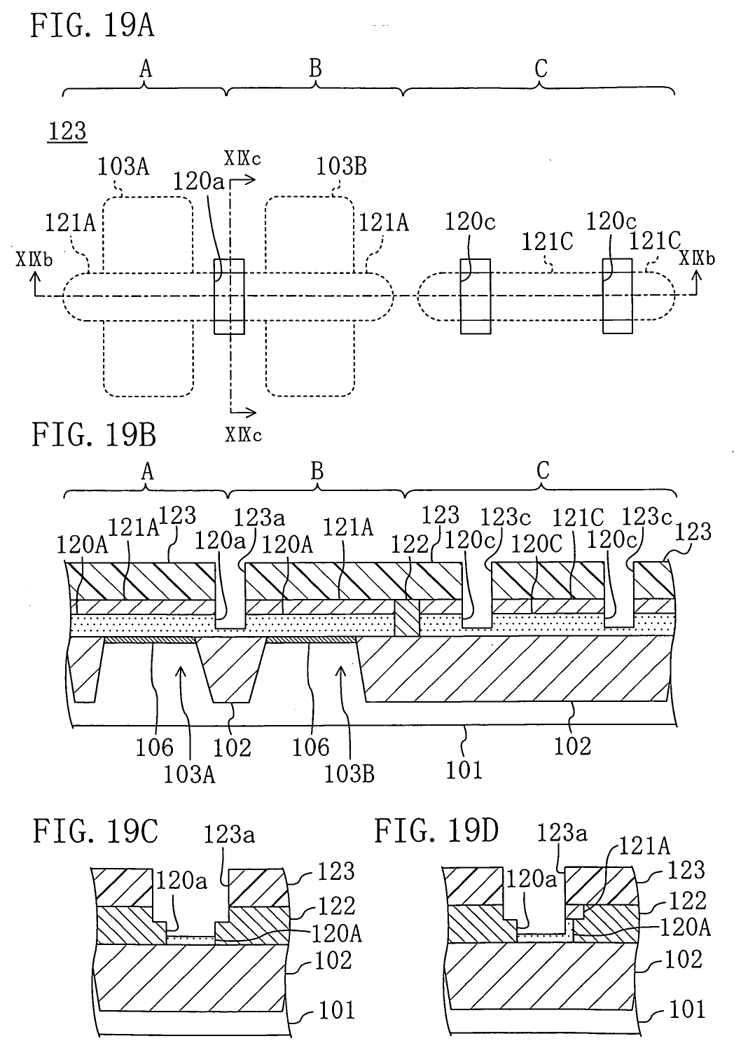

FIGS. 19A through 19D to FIGS. 25A through 25C are plan views and cross-sectional views showing structures in respective process steps of a method for fabricating a semiconductor device according to the second embodiment in the order of fabrication. In FIGS. 19A through 19D to FIGS. 25A through 25C, components also shown in FIGS. 8A through 8C to FIGS. 15A through 15C are denoted by the same reference numerals, and description thereof will be omitted.

First, as illustrated in FIGS. 19A through 19D in the same manner as FIGS. 9A through 9D of the first embodiment, using a first resist mask 123 as a mask, a first opening 120a and second openings 120c are formed in a portion connecting a first gate electrode and a second gate electrode in a first silicon gate electrode 120A formed by patterning in an n-FET region A and a p-FET region B and in portions connecting a resistor body and contact regions in a silicon resistor 120C formed by patterning in a resistor region C. A feature of the second embodiment is that polysilicon remains on the bottoms of the first opening 120a and the second openings 120c. At this time, as illustrated in FIG. 19D, polysilicon may also remain on the side walls of the openings 120a and 120c. In addition, as illustrated in FIGS. 19A and 19C, to easily form the first opening 120a, for example, an opening in the first protective insulating film 121A is larger than that in the underlying first silicon gate electrode 120A, for example. If the upper level of the diffusion preventing films 135 is lower than those of the first silicon gate electrode 120A and the silicon resistor 120C, each of the openings 120a and 120c may be in the shape of a trench with which patterning is more easily performed. In consideration of misalignment, the short sides of the openings 120a and 120c preferably do not overlap with the first silicon gate electrode 120A and the silicon resistor 120C. However, even when such overlapping occurs, no substantial problems arise.

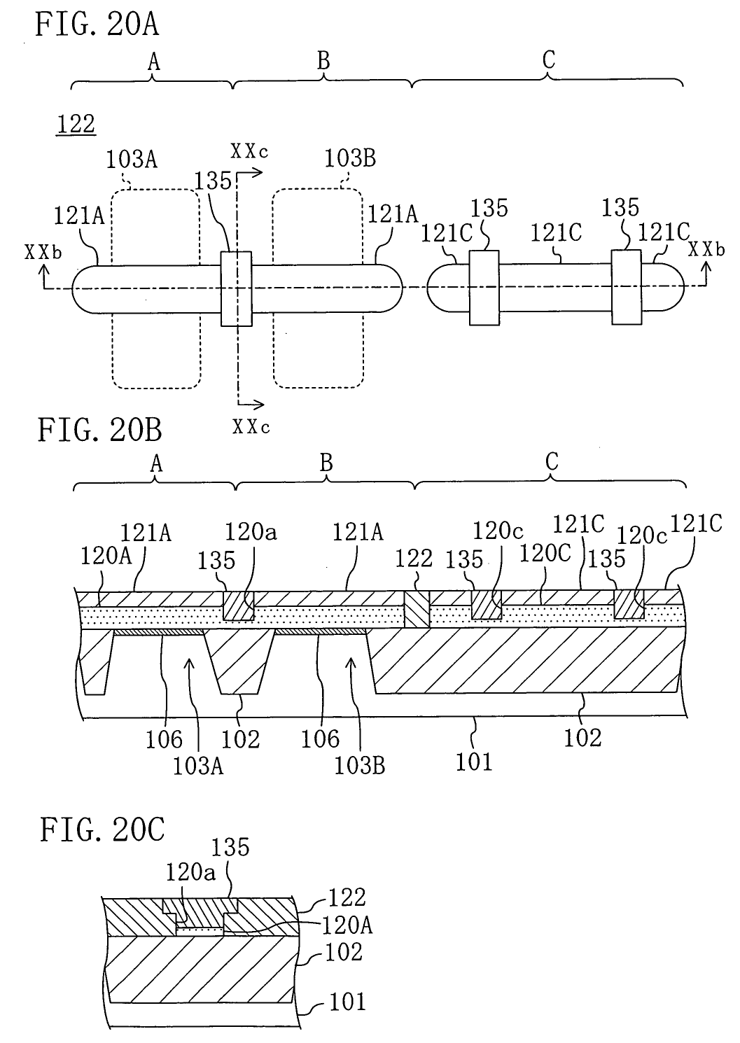

Next, as shown in FIGS. 20A through 20C, the first resist mask 123 is removed, and then a silicon oxide film is deposited by, for example, CVD over a third protective insulating film 122 so that the first opening 120a and the second openings 120c are filled therewith. Subsequently, a portion of the silicon oxide film located on the third protective insulating film 122 is removed by, for example, CMP, thereby forming diffusion preventing films 135 of silicon oxide in the first opening 120a in the first silicon gate electrode 120A and the second openings 120c in the silicon resistor 120C. In the second embodiment, the openings 120a and 120c are also filled with the diffusion preventing films 135. However, voids may be partially formed in the diffusion preventing film 135. In such a case, no substantial problems occur.

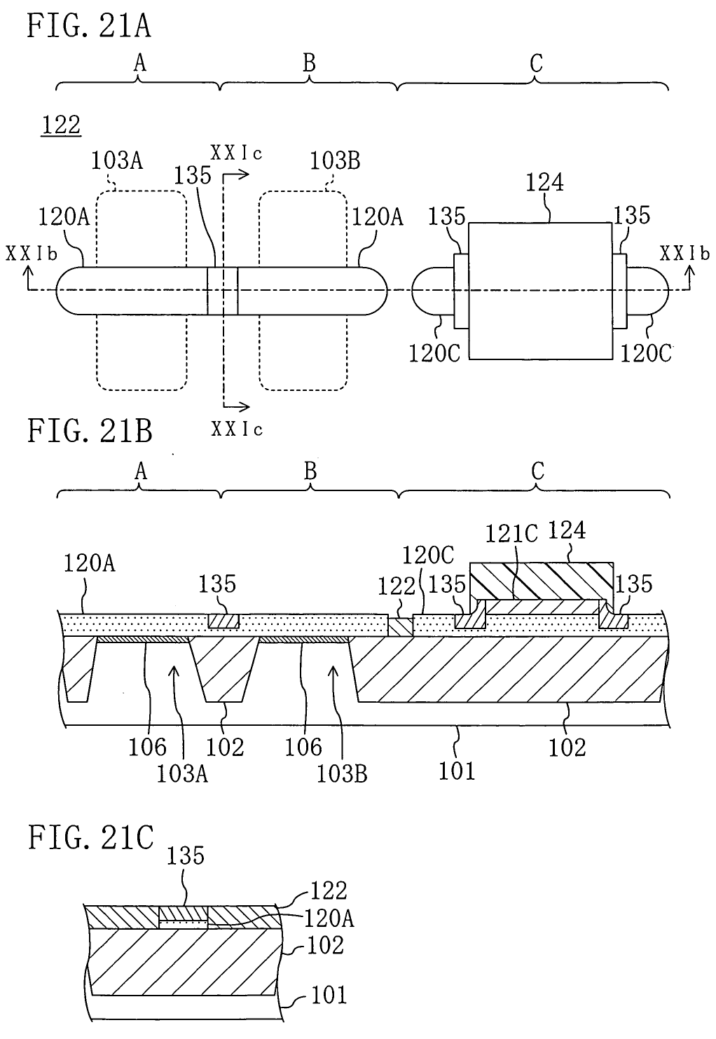

Then, as shown in FIGS. 21A through 21C, a second resist film 124 for masking a region of the silicon resistor 120C sandwiched between two diffusion preventing films 135 is formed on a second protective insulating film 121C by lithography. Using the second resist film 124 as a mask, both ends of each of the first protective insulating film 121A and the second protective insulating film 121C are removed by wet etching using hydrofluoric acid, for example.

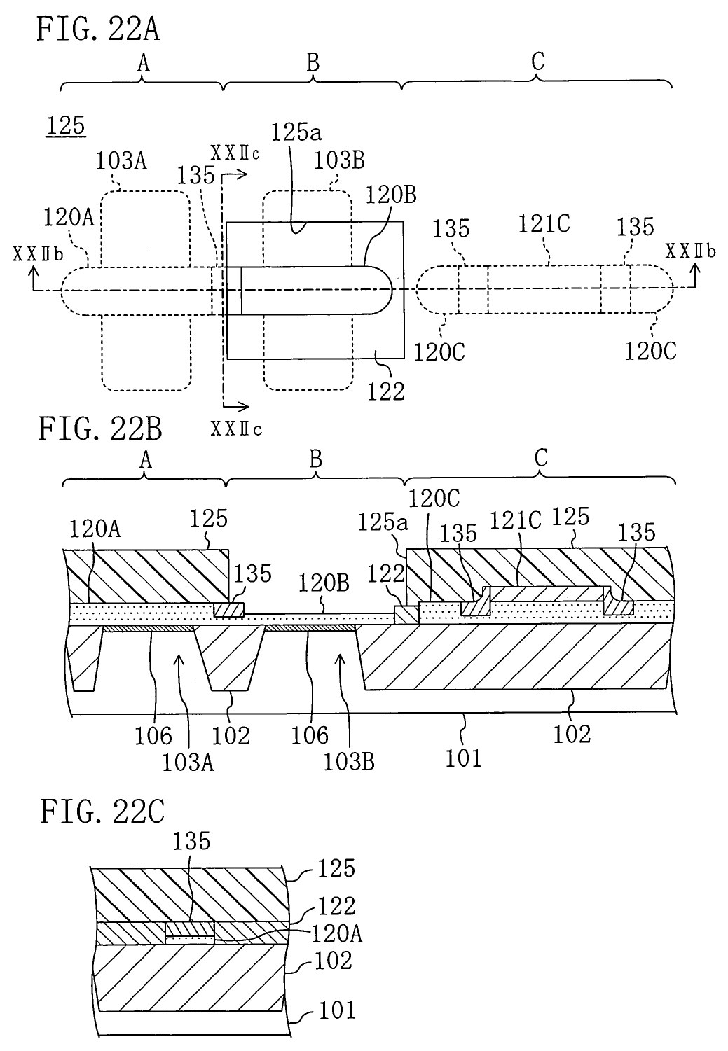

Thereafter, as shown in FIGS. 22A through 22C, the second resist film 124 is removed, and then a third resist film 125 having an opening pattern 125a in which the p-FET region B is exposed is formed on the third protective insulating film 122 by lithography. Subsequently, using the third resist film 125 as a mask, dry etching containing a chlorine gas as a main component is performed on the first silicon gate electrode 120A in the p-FET region B, thereby obtaining a second silicon gate electrode 120B with a thickness of 25 nm out of the first silicon gate electrode 120A.

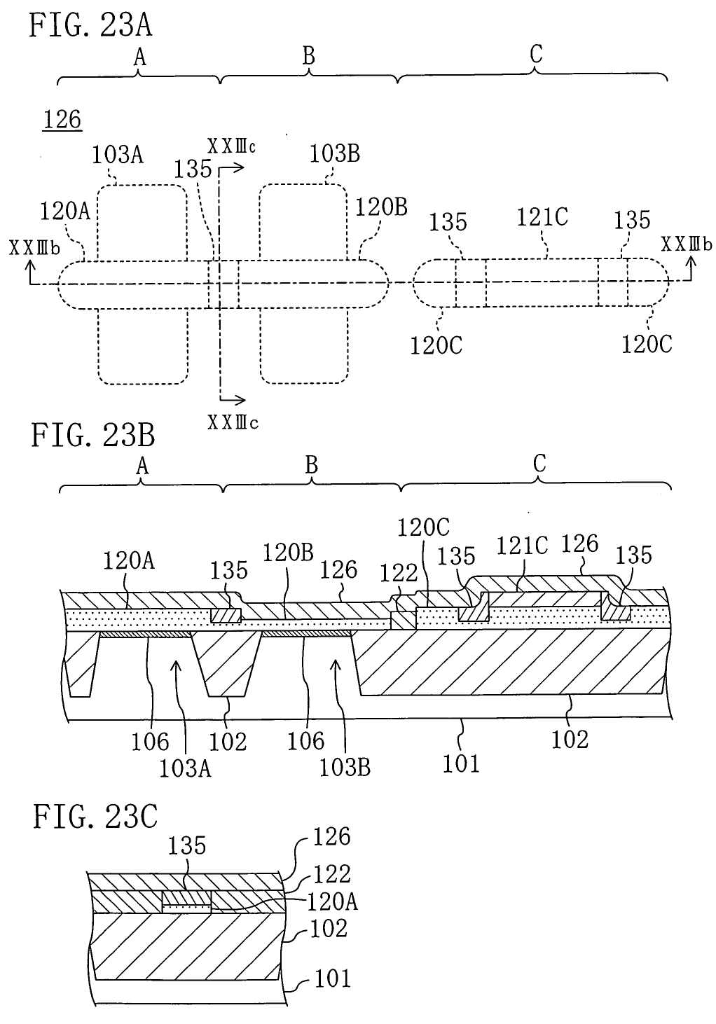

Subsequently, as shown in FIGS. 23A through 23C, the third resist film 125 is removed, and then a metal film 126 of nickel (Ni) is deposited by, for example, sputtering to a thickness of 35 nm over the entire surface of the third protective insulating film 122 including the first silicon gate electrode 120A, the second silicon gate electrode 120B, the silicon resistor 120C partially to be contact regions and the second protective insulating film 121C.

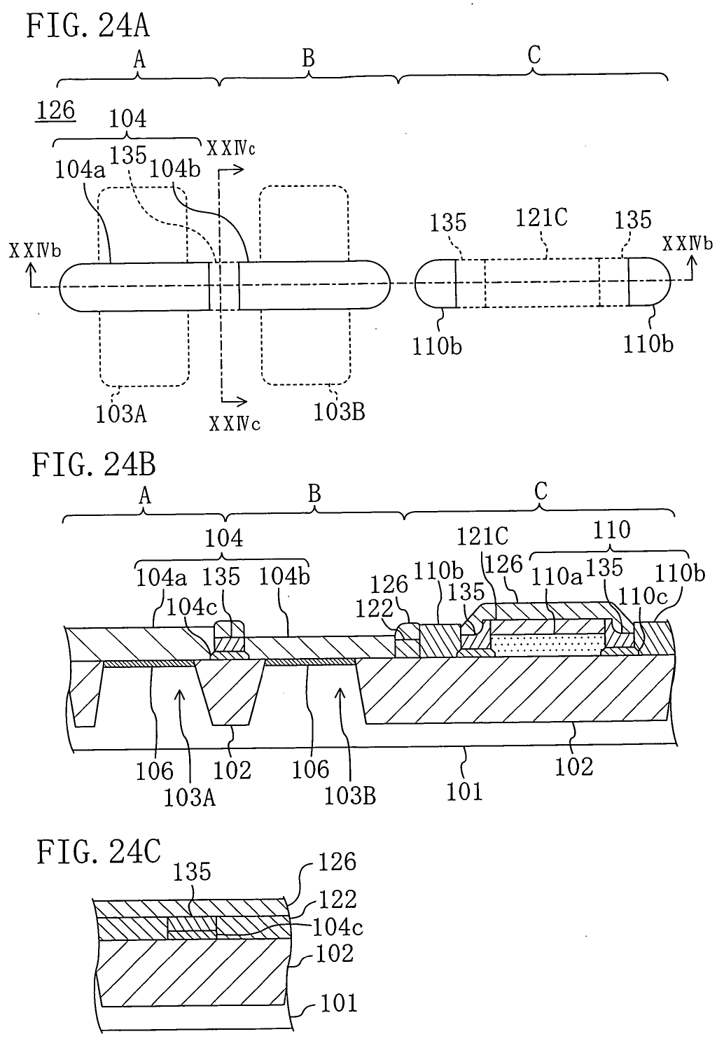

Then, as shown in FIGS. 24A through 24C, heat treatment is performed on the semiconductor substrate 101 at 400° C. in a nitrogen atmosphere by, for example, rapid thermal annealing (RTA), thereby causing silicidation between the metal film 126 and each of the first silicon gate electrode 120A, the second silicon gate electrode 120B and the silicon resistor 120C. As a result, these polysilicon parts are fully silicided. Specifically, the first silicon gate electrode 120A is changed to a FUSI first gate electrode 104a made of NiSi and the second silicon gate electrode 120B which is thinner than the first silicon gate electrode 120A is changed to a FUSI second gate electrode 104b made of Ni₃Si. In the resistor region C, portions of the silicon resistor 120C located outside the diffusion preventing films 105 are changed to contact regions 110b made of NiSi. A portion of the silicon resistor 120C located inside the diffusion preventing films 105 is covered with the second protective insulating film 121C, so that no silicidation occurs, and this silicon resistor 120C is changed to a resistor body 110a made of polysilicon. At this time, since the diffusion preventing films 135 made of an insulating material and preventing diffusion of metal (nickel) are provided in the connecting portion between the first gate electrode 104a and the second gate electrode 104b and the connecting portions between the resistor body 110a and the contact regions 110b, formation of intermediate phase films 104c and 110c having metal contents different from predetermined metal contents is suppressed. As shown in FIGS. 19B and 19C, polysilicon is left on the bottoms of the first opening 120a and the second openings 120c, so that the conductive intermediate phase films 104c and 110c are formed. As a result, it is possible to establish electrical connection in the common gate electrode 104 and the resistor 110 themselves. In addition, since the amount of the intermediate phase films 104c and 110c is very small, the intermediate phase films 104c and 110c enter the first gate electrode 104a, the second gate electrode 104b and the resistor body 110a to small extents. If the diffusion preventing films 135 are thinner than the polysilicon films such as the first silicon gate electrode 120A in the first opening 120a and the second openings 120c as shown in FIGS. 21A through 21C, intermediate phase films 104c and 110c can also be formed on the diffusion preventing films 135. However, even in such a case, since the amount of these intermediate phase films 104c and 110c is very small, the intermediate phase films 104c and 110c enter the first gate electrode 104a, the second gate electrode 104b and the resistor body 110a to small extents.

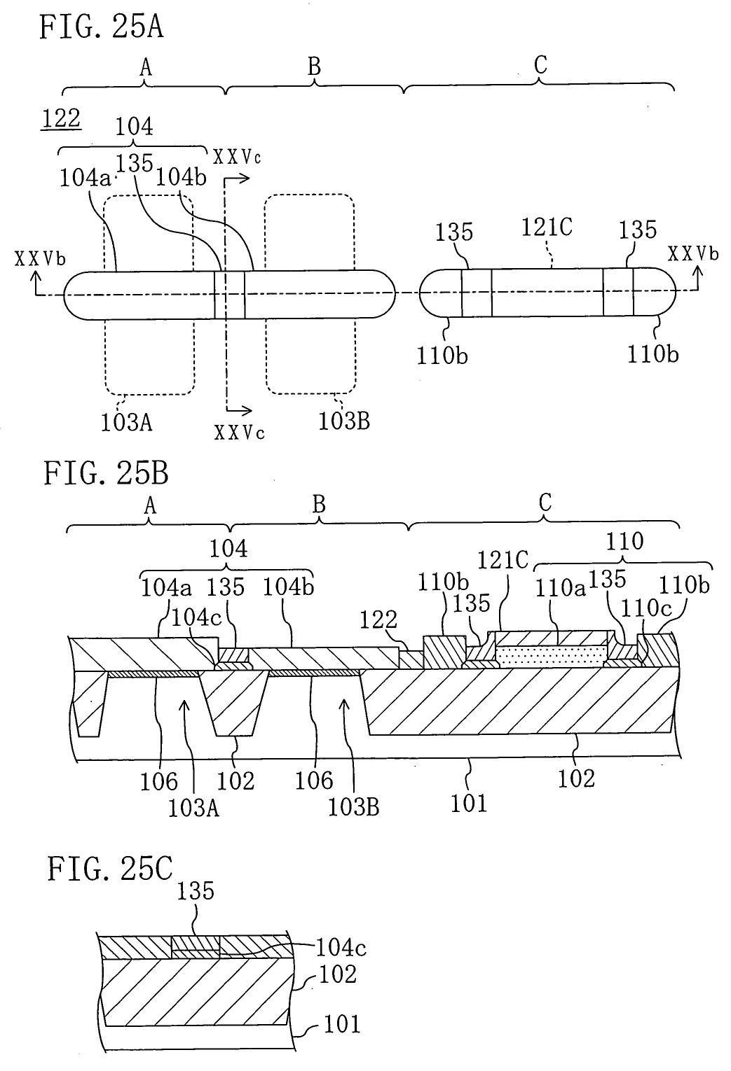

Subsequently, as shown in FIGS. 25A through 25C, the unreacted portion of the metal film 126 is etched with, for example, a solution in which sulfuric acid and a hydrogen peroxide solution are mixed, thereby removing the unreacted portion. Thereafter, though not shown, an interlayer insulating film is deposited over the entire surfaces of the n-FET region A, the p-FET region B and the resistor region C, and contact holes and interconnections are formed by known methods.

In this manner, with the method for fabricating a semiconductor device according to the second embodiment, the insulating diffusion preventing films 135 for preventing metal diffusion are at least partially formed in the connecting portion between the first gate electrode 104a and the second gate electrode 104b in the n-FET region A and the p-FET region B and in the connecting portions between the resistor body 110a and the contact regions 110b in the resistor region C. Accordingly, formation of intermediate phase films 104c and 110c due to diffusion of metal for silicidation is suppressed.

In addition, an n-FET and a p-FET having a FUSI common gate electrode 104 and a resistor 110 having a FUSI contact regions 110b are formed at a time.

As in the first embodiment, in the process step shown in FIGS. 19A through 19D, the first opening 120a and the second openings 120c are formed in the first silicon gate electrode 120A and the silicon resistor 120C, respectively, with the first protective insulating film 121A and the second protective insulating film 121C being formed. Alternatively, as shown in FIGS. 22A through 22C, the openings 120a and 120c may be formed after the thickness of the first silicon gate electrode 120A in the p-FET region B is reduced to form the second silicon gate electrode 120B.

The first protective insulating film 121A and the second protective film 121C are not necessarily formed. For example, in the processes shown in FIGS. 19A through 19D to FIGS. 22A through 22C, these processes may be performed with the first silicon gate electrode 120A and the silicon resistor 120C exposed using the resist films 123, 124 and 125 and not using the protective insulating films 121A and 121C.

In the resistor region C, if a portion of the metal film 126 located on a region (i.e., resistor body 110a) of the silicon resistor 120C sandwiched between the diffusion preventing films 135 is removed after the process step shown in FIGS. 23A through 23C, the second protective insulating film 121C and the second resist film 124 are unnecessary.

### Embodiment 3

Hereinafter, a third embodiment of the present invention will be described with reference to the drawings.

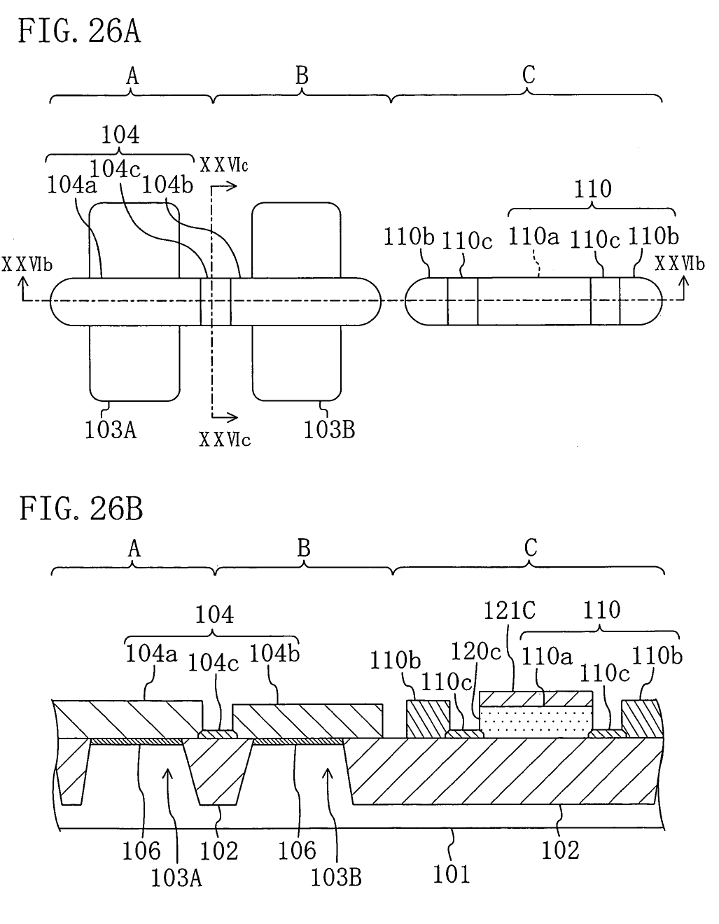

FIGS. 26A and 26B illustrate a semiconductor device according to the third embodiment. FIG. 26A is a plan view and FIG. 26B is a cross-sectional view taken along the line XXVIb-XXVIb in FIG. 26A. In FIGS. 26A and 26B, components also shown in FIGS. 16A and 16B are denoted by the same reference numerals, and description thereof will be omitted.

As illustrated in FIGS. 26A and 26B, in the third embodiment, no diffusion preventing film 135 is provided in a connecting portion of a common gate electrode 104, and an intermediate phase film 104c thinner than gate electrodes 104a and 104b is left on the bottom of a first opening 120a. No diffusion preventing film 135 is also provided in a portion connecting a resistor body 110a and a contact region 110b in a resistor 110, and an intermediate phase film 110c thinner than the resistor body 110a and the contact region 110b is left on the bottom of a second opening 120c. It should be noted that if another insulating film such as an interlayer insulating film is formed on a third protective insulating film 122, spaces on the intermediate phase films 104c and 110c can be filled with an insulating film.

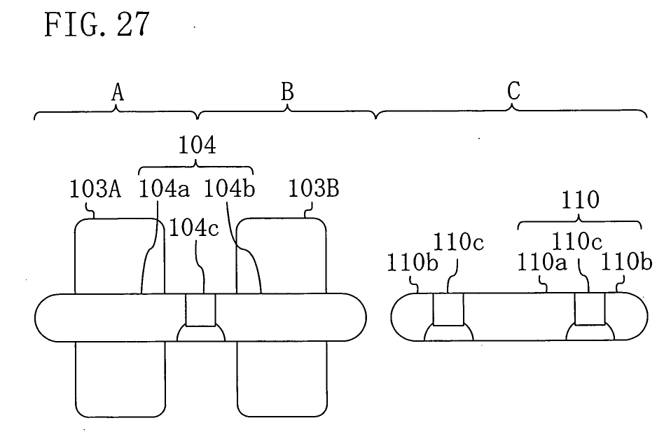

In a modified example shown in FIG. 27, the thickness of the intermediate phase films 104c and 110c may vary (i.e., may be nonuniform) from one side to the other side.

In this manner, in the semiconductor device of the third embodiment, the thickness of the connection portion between the first gate electrode 104a and the second gate electrode 104b is small in the common gate electrode 104 in an n-FET region A and a p-FET region B and the thickness of connecting portions between the resistor body 110a and the contact regions 110b is also small in the resistor region C. Accordingly, the amount of each of the intermediate phase films 104c and 110c is small. That is, each of the connecting portions which are interfaces between different metal contents has a small area in cross section, thus suppressing diffusion of metal for silicidation. As a result, the threshold voltages of the FETs and the resistance value of the resistor 110 vary in small circuit areas.

In addition, the conductive intermediate phase films 104c and 110c remain in the connecting portions, so that electrical connection is maintained in the common gate electrode 104 and the resistor 110. As a result, the performance of the semiconductor device is enhanced and the integration degree thereof is increased.

Hereinafter, a method for fabricating a semiconductor device having the foregoing structure will be described with reference to the drawings.

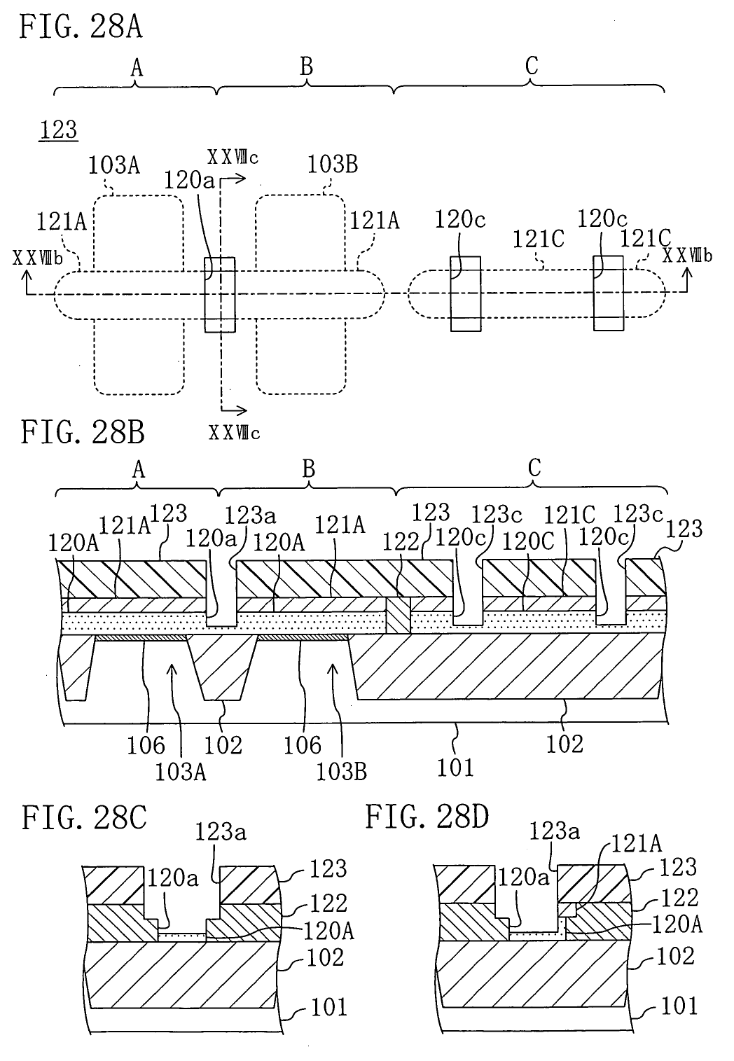

FIGS. 28A through 28D to FIGS. 33A through 33C are plan views and cross-sectional views showing structures in respective process steps of a method for fabricating a semiconductor device according to the third embodiment in the order of fabrication. In FIGS. 28A through 28D to FIGS. 33A through 33C, components also shown in FIGS. 8A through 8C to FIGS. 15A through 15C are denoted by the same reference numerals, and description thereof will be omitted.

First, as illustrated in FIGS. 28A through 28D in the same manner as FIGS. 9A through 9D of the first embodiment, using a first resist mask 123 as a mask, a first opening 120a and second openings 120c are formed in a portion connecting a first gate electrode and a second gate electrode in a first silicon gate electrode 120A formed by patterning on an n-FET region A and a p-FET region B and in portions connecting a resistor body and contact regions in a silicon resistor 120C formed by patterning on a resistor region C. A feature of the third embodiment is that polysilicon remains on the bottoms of the first opening 120a and the second openings 120c. At this time, as illustrated in FIG. 28D, polysilicon may remain on the side walls of the openings 120a and 120c. In addition, as illustrated in FIGS. 28A and 28C, to easily form the first opening 120a, for example, an opening in the first protective insulating film 121A, for example, is larger than that in the underlying the first silicon gate electrode 120A, for example. If the upper level of the diffusion preventing films 135 is lower than those of the first silicon gate electrode 120A and the silicon resistor 120C, each of the openings 120a and 120c may be in the shape of a trench with which patterning is more easily performed. In consideration of misalignment, the short sides of the openings 120a and 120c preferably do not overlap with the first silicon gate electrode 120A and the silicon resistor 120C. However, even when such overlapping occurs, no substantial problems arise.

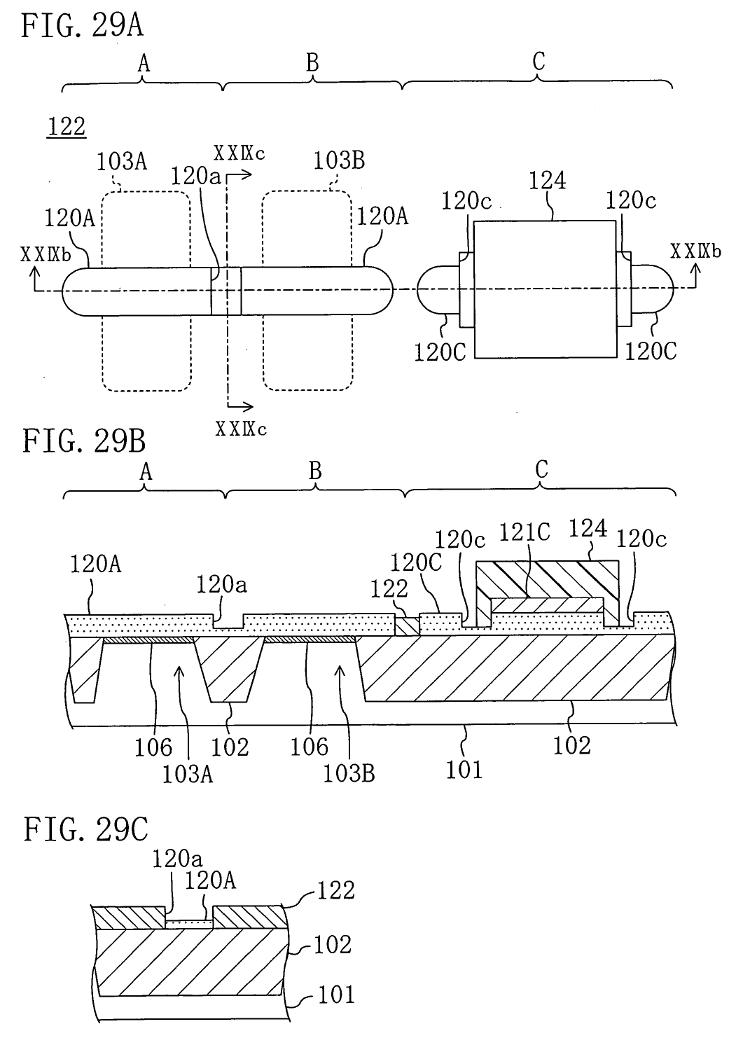

Next, as shown in FIGS. 29A through 29C, the first resist mask 123 is removed, and then a second resist film 124 for masking a region of the silicon resistor 120C sandwiched between two second openings 120c is formed on a second protective insulating film 121C by lithography. Using the second resist film 124 as a mask, both ends of each of the first protective insulating film 121A and the second protective insulating film 121C are removed by wet etching using hydrofluoric acid, for example.

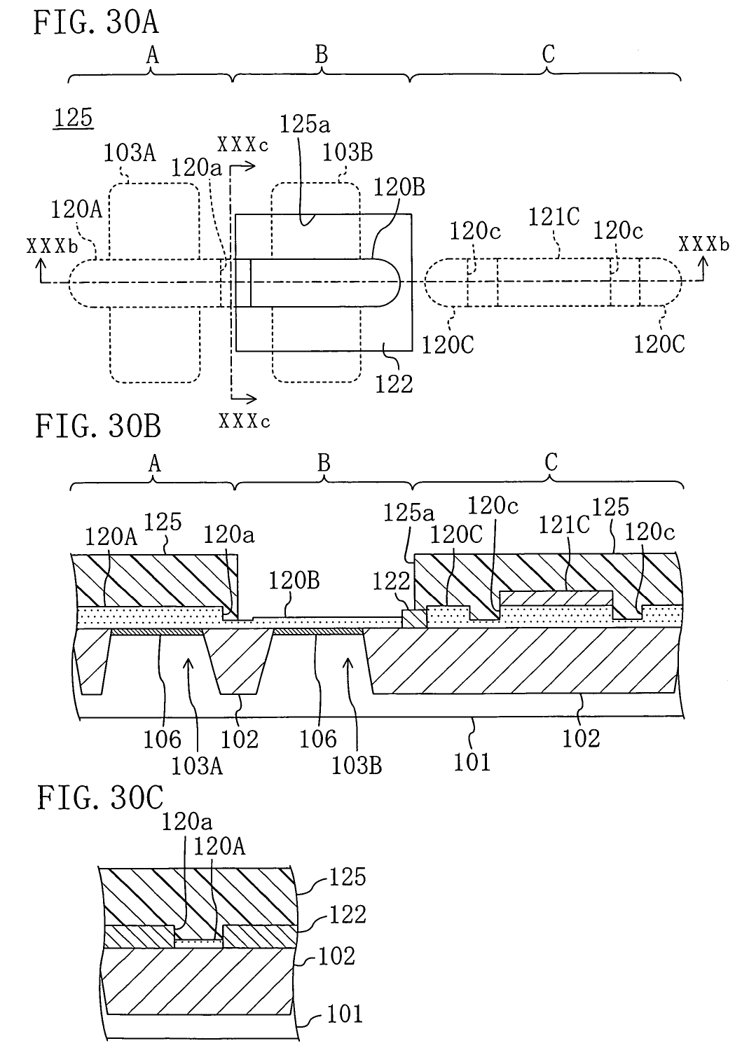

Thereafter, as shown in FIGS. 30A through 30C, the second resist film 124 is removed, and then a third resist film 125 having an opening pattern 125a in which the p-FET region B is exposed is formed on the third protective insulating film 122 by lithography. Subsequently, using the third resist film 125 as a mask, dry etching containing a chlorine gas as a main component is performed on the first silicon gate electrode 120A in the p-FET region B, thereby obtaining a second silicon gate electrode 120B with a thickness of 25 nm out of the first silicon gate electrode 120A.

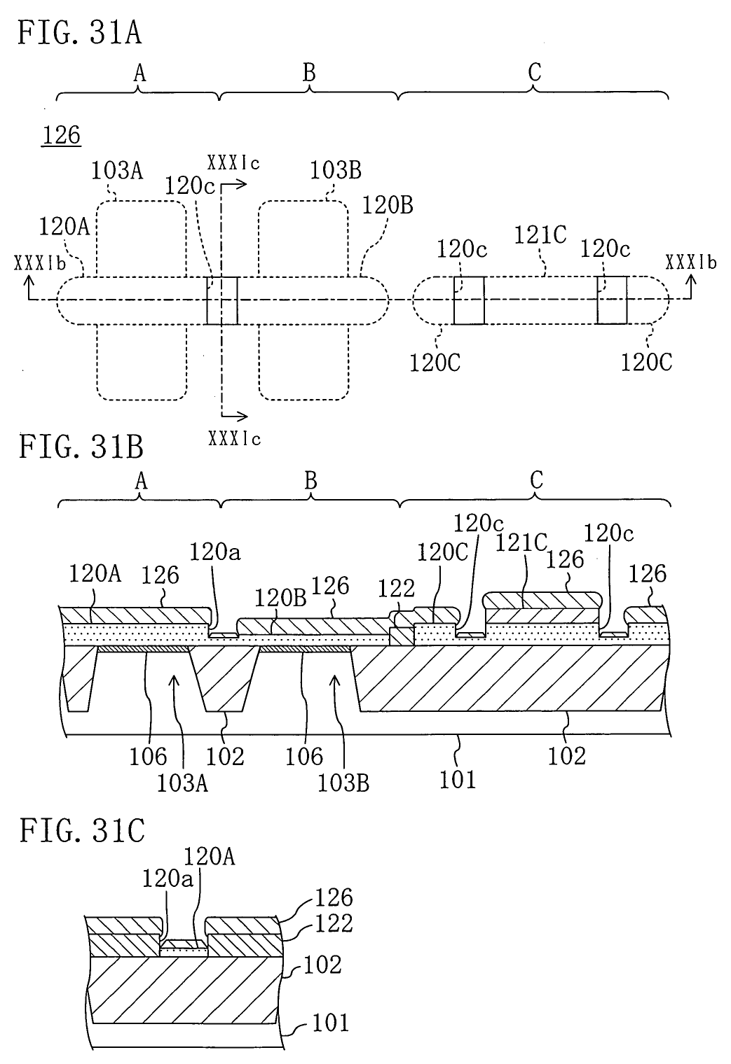

Subsequently, as shown in FIGS. 31A through 31C, the third resist film 125 is removed, and then a metal film 126 of nickel (Ni) is deposited by, for example, sputtering to a thickness of 35 nm over the entire surface of the third protective insulating film 122 including the first silicon gate electrode 120A, the second silicon gate electrode 120B, the silicon resistor 120C partially to be contact regions, and the second protective insulating film 121C.

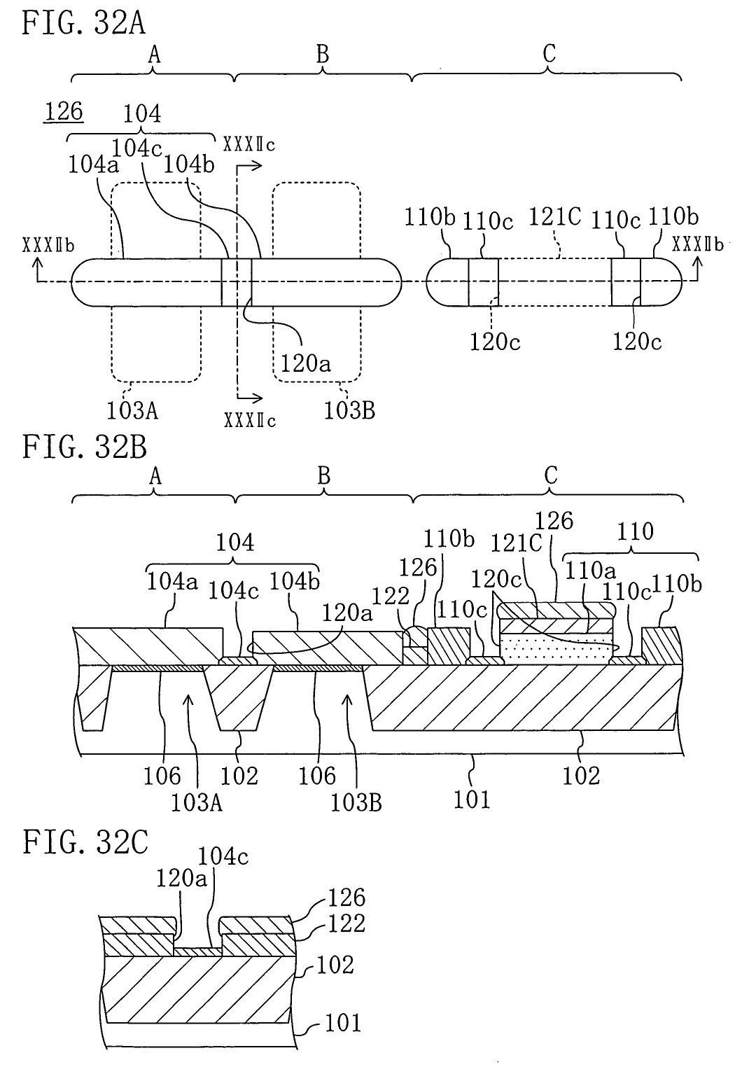

Then, as shown in FIGS. 32A through 32C, heat treatment is performed on the semiconductor substrate 101 at 400° C. in a nitrogen atmosphere by, for example, rapid thermal annealing (RTA), thereby causing silicidation between the metal film 126 and each of the first silicon gate electrode 120A, the second silicon gate electrode 120B and the silicon resistor 120C. As a result, these polysilicon parts are fully silicided. Specifically, the first silicon gate electrode 120A is changed to a FUSI first gate electrode 104a made of NiSi and the second silicon gate electrode 120B which is thinner than the first silicon gate electrode 120A is changed to a FUSI second gate electrode 104b made of Ni₃Si. In the resistor region C, portions of the silicon resistor 120C located outside the diffusion preventing films 105 are changed to contact regions 110b made of NiSi. A portion of the silicon resistor 120C located inside the diffusion preventing films 105 is covered with the second protective insulating film 121C, so that no silicidation occurs, and this portion is changed to a resistor body 110a made of polysilicon. At this time, since the first opening 120a and the second openings 120c are provided in the connecting portion between the first gate electrode 104a and the second gate electrode 104b and the connecting portions between the resistor body 110a and the contact regions 110b and polysilicon remains on their bottoms, formation of conductive intermediate phase films 104c and 110c having metal contents different from predetermined metal contents is suppressed. As a result, it is possible to establish electrical connection in the common gate electrode 104 and the resistor 110 themselves. In addition, since the amount of the intermediate phase films 104c and 110c is very small, the intermediate phase films 104c and 110c enter the first gate electrode 104a, the second gate electrode 104b and the resistor body 110a to small extents. Unlike the second embodiment, in the third embodiment, polysilicon remaining on the bottoms of the first opening 120a and the second openings 120c is also silicided in the silicidation process shown in FIGS. 31A through 31C, the conductivity of the intermediate phase films 104c and 110c is higher than that in the second embodiment.

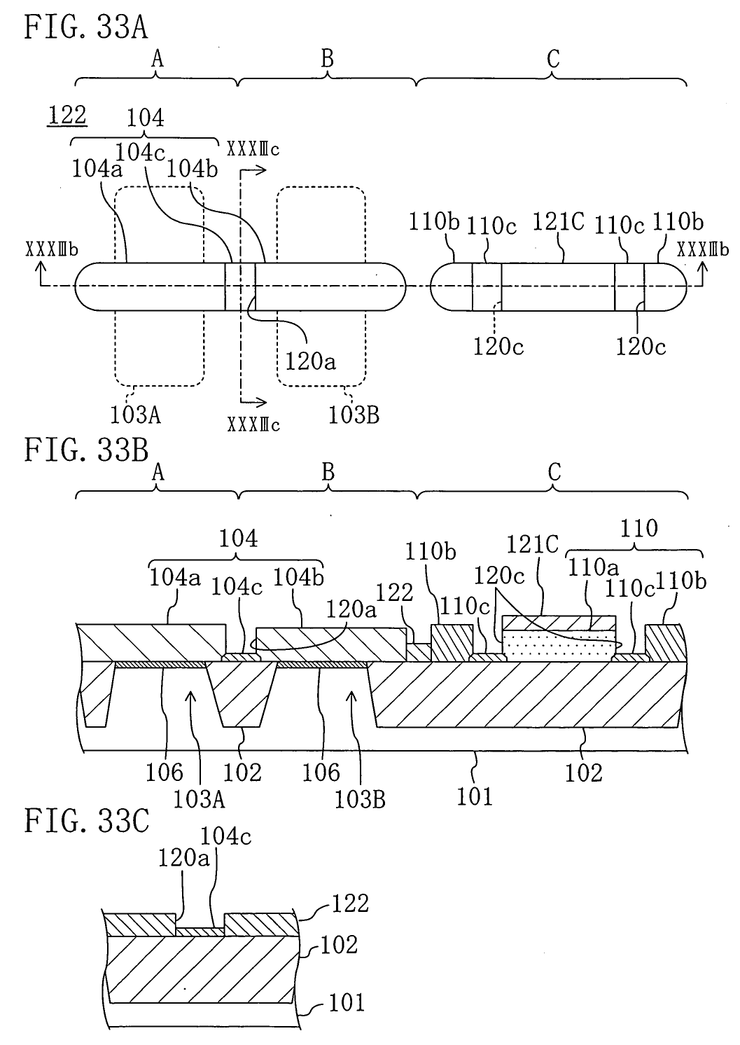

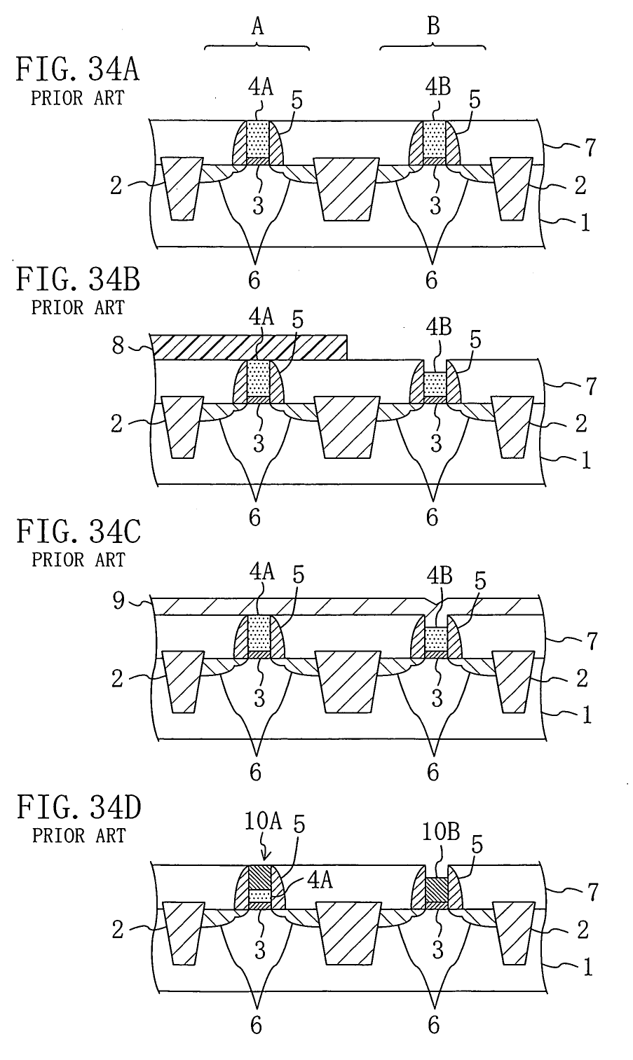

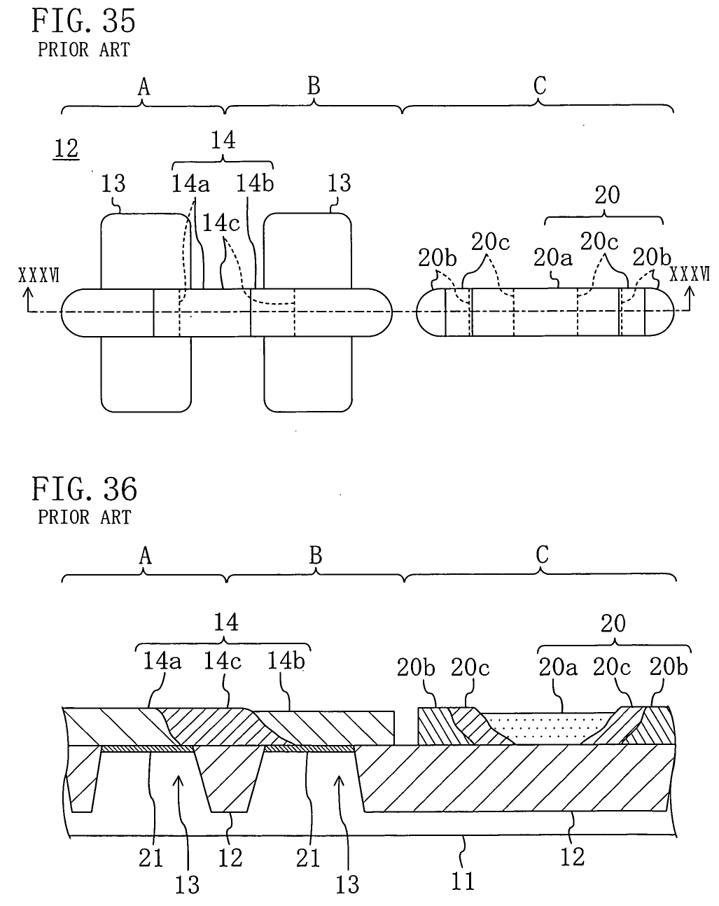

Subsequently, as shown in FIGS. 33A through 33C, the unreacted portion of the metal film 126 is etched with, for example, a solution in which sulfuric acid and a hydrogen peroxide solution are mixed, thereby removing the unreacted portion. Thereafter, though not shown, an interlayer insulating film is deposited over the entire surfaces of the n-FET region A, the p-FET region B and the resistor region C, and contact holes and interconnections are formed by known methods.

In this manner, with the method for fabricating a semiconductor device according to the third embodiment, the connecting portion between the first gate electrode 104a and the second gate electrode 104b in the n-FET region A and the p-FET region B and the connecting portions between the resistor body 110a and the contact regions 110b in the resistor region C are partially removed, thus suppressing formation of intermediate phase films 104c and 110c due to diffusion of metal for silicidation.

In addition, an n-FET and a p-FET having a FUSI common gate electrode 104 and a resistor 110 having FUSI contact regions 110b are formed at a time.

As in the first embodiment, in the process step shown in FIGS. 28A through 28D, the first opening 120a and the second openings 120c are formed in the first silicon gate electrode 120A and the silicon resistor 120C, respectively, with the first protective insulating film 121A and the second protective insulating film 121C being formed. Alternatively, as shown in FIGS. 30A through 30C, the openings 120a and 120c may be formed after the thickness of the first silicon gate electrode 120A in the p-FET region B is reduced to form the second silicon gate electrode 120B.

The first protective insulating film 121A and the second protective film 121C are not necessarily formed. For example, in the processes shown in FIGS. 28A through 28D to FIGS. 30A through 30C, the processes may be performed with the first silicon gate electrode 120A and the silicon resistor 120C exposed using the resist films 123, 124 and 125 and not using the protective insulating films 121A and 121C.

In the resistor region C, if a portion of the metal film 126 located on a region (i.e., resistor body 110a) of the silicon resistor 120C sandwiched between the diffusion preventing films 135 is removed after the process step shown in FIGS. 23A through 23C, the second protective insulating film 121C and the second resist film 124 are unnecessary.

In the first through third embodiments, a well region, source/drain regions and a threshold-value-control doped region are formed in each of the active regions 103A and 103B and sidewall spacers are formed for each of the gate electrodes 104a and 104b in the n-FET region A and the p-FET region B. These components are not shown in the drawings.

In the foregoing embodiments, the metal compositions of the first gate electrode 104a and the second gate electrode 104b are NiSi and Ni₃Si, respectively, but are not limited to these materials. Alternatively, different metal silicides may be used for the gate electrodes 104a and 104b. For example, NiSi may be used for the first gate electrode 104a and PtSi may be used for the second gate electrode 104b. The conductive material of the contact regions 110b in the resistor 110 is not necessarily NiSi, but may be Ni₃Si. Conductive materials other than NiSi and Ni₃Si may also be used.

In the foregoing embodiments, the resistor 110 is described as an example of an element including a portion connecting a FUSI structure and a non-FUSI structure. However, the present invention is effective even when a FET has a non-FUSI structure and a resistor has a FUSI structure including a portion connecting a resistor body having a low metal content and a contact region having a high metal content.

In the foregoing embodiments, the FET regions A and B and the resistor region C are adjacent to one another on the single semiconductor substrate 101. Alternatively, the FET regions A and B and the resistor region C are not necessarily adjacent to one another and are not necessarily formed on the single semiconductor substrate 101.

In the foregoing embodiments, FETs and a resistor are described as an example of elements. However, each of these FETs and the resistor may be another element having an integrated FUSI structure including a connecting portion between portions having different metal contents or another integrated element including a connection portion between a FUSI structure and a non-FUSI structure. For example, the present invention is applicable to FETs having a common gate electrode which is not fully-silicided and a FUSI contact region connected to the common gate electrode and a fuse element, for example.

As described above, with a semiconductor device and a method for fabricating the device according to the present invention, metal diffusion between FUSI structures having different metal contents is prevented or suppressed so that formation of intermediate phase films due to the metal diffusion is suppressed. Accordingly, the circuit area is reduced and variation of electrical characteristics is prevented. The present invention is especially useful for a semiconductor device including a field effect structure with a FUSI structure and a method for fabricating such a semiconductor device.

What is claimed is:

1. A semiconductor device, comprising:
a first field-effect transistor including a first gate electrode; and
a second field-effect transistor including a second gate electrode,
wherein the first gate electrode and the second gate electrode are integrated using a connecting portion and are fully silicided with metal in such a manner that the fist and second gate electrodes have different metal contents, and
a diffusion preventing film for preventing the metal from diffusing between the first and second gate electrodes is formed in at least a portion of the connecting portion.

2. The semiconductor device of claim 1, wherein the diffusion preventing film is made of a first conductor covering the entire connecting portion.

3. The semiconductor device of claim 1, wherein the diffusion preventing film is made of a first conductor partially covering the connecting portion.

4. The semiconductor device of claim 3, wherein a second conductor film is provided in one side of the connecting portion, and
the diffusion preventing film is formed in the other portion of the connecting portion.

5. The semiconductor device of claim 3, wherein a second conductor film is provided in a lower portion of the connecting portion, and
the diffusion preventing film is provided on the second conductor film.

6. The semiconductor device of claim 5, wherein the second conductor film is made of a silicide having a metal content between a metal content of the first gate electrode and a metal content of the second gate electrode.

7. The semiconductor device of claim 5, wherein a third conductor film is formed on the diffusion preventing film.

8. The semiconductor device of claim 7, wherein the third conductor film contains a metal for siliciding the first gate electrode and the second gate electrode.

9. The semiconductor device of claim 3, wherein a second conductor film is provided in an upper portion of the connecting portion, and
the diffusion preventing film is provided under the second conductor film.

10. The semiconductor device of claim 9, wherein the second conductor film is made of a silicide having a metal content between a metal content of the first gate electrode and a metal content of the second gate electrode.

11. The semiconductor device of claim 3, wherein the diffusion preventing film between the first gate electrode and the second gate electrode has a cross-sectional area larger than that of the connecting portion between the first gate electrode and the second gate electrode.

12. The semiconductor device of claim 2, wherein the first conductor is made of another metal or a metal compound which is not silicided.

13. The semiconductor device of claim 3, wherein the first conductor is another metal or a metal compound which is not silicided.

14. The semiconductor device of claim 1, wherein the diffusion preventing film is made of an insulator partially covering the connecting portion.

15. The semiconductor device of claim 14, wherein a second conductor film is provided in a lower portion of the connecting portion, and
the diffusion preventing film is provided on the second conductor film.

16. The semiconductor device of claim 15, wherein the second conductor film is made of a silicide having a metal content between a metal content of the first gate electrode and a metal content of the second gate electrode.

17. The semiconductor device of claim 14, wherein the diffusion preventing film between the first gate electrode and the second gate electrode has a cross-sectional area larger than that of the connecting portion between the first gate electrode and the second gate electrode.

18. The semiconductor device of claim 14, wherein a third conductor film is formed on the diffusion preventing film.

19. The semiconductor device of claim 18, wherein the third conductor film contains a metal for siliciding the first gate electrode and the second gate electrode.

20. The semiconductor device of claim 14, wherein a second conductor film is provided in one side of the connecting portion, and
the diffusion preventing film is formed in the other portion of the connecting portion.

21. The semiconductor device of claim 20, wherein the diffusion preventing film between the first gate electrode and the second gate electrode has a cross-sectional area larger than that of the connecting portion between the first gate electrode and the second gate electrode.

22. The semiconductor device of claim 1, wherein one of the first and second field-effect transistors has an n-type conductivity and the other field-effect transistor has a p-type conductivity.

23. The semiconductor device of claim 22, wherein one of the first and second field-effect transistors whose first or second gate electrode has a higher metal content has a p-type conductivity, and
the other field-effect transistor whose first or second gate electrode has a lower metal content has an n-type conductivity.

24. The semiconductor device of claim 1, further comprising a resistor including a resistor body containing silicon and a contact region formed by fully siliciding a portion of the resistor body with the metal,
wherein a diffusion preventing film for preventing the metal from diffusing from the contact region to the resistor body is formed in a connection portion between the resistor body and the contact region.

25. A method for fabricating a semiconductor device including a first field-effect transistor including a first gate electrode and a second field-effect transistor including a second gate electrode, the method comprising the steps of:
(a) forming, on a semiconductor region, a silicon gate electrode made of silicon and including a first-gate-electrode region and a second-gate-electrode region;
(b) forming, in a connecting portion between the first-gate-electrode region and the second-gate-electrode region in the silicon gate electrode, a first trench in which at least a portion of each of the first-gate-electrode region and the second-gate-electrode region is exposed;
(c) forming, in the first trench, a diffusion preventing film for preventing diffusion of a metal for siliciding the silicon gate electrode;
(d) forming a metal film on the silicon gate electrode in which the diffusion preventing film is formed; and
(e) performing heat treatment on the metal film so that the first-gate-electrode region and the second-gate-electrode region are fully silicided to have different metal contents, thereby forming the first gate electrode and the second gate electrode.

26. The method of claim 25, wherein the diffusion preventing film is made of another metal or a metal compound which is not silicided with the metal film.

27. The method of claim 25, further comprising the step:
(f) removing an upper portion of one of the first-gate-electrode region and the second-gate-electrode region in the silicon gate electrode by etching, between the steps of (a) and (d).

28. The method of claim 25, wherein the step (d) includes the step of making the metal film have different thicknesses between portions on the first-gate-electrode region and the second-gate-electrode region in the silicon gate electrode.

29. The method of claim 25, wherein in the step (b), each of the first-gate-electrode region and the second-gate-electrode region exposed from a wall of the first trench has a cross-sectional area larger than that of a connecting portion between the first-gate-electrode region and the second-gate-electrode region.

30. A method for fabricating a semiconductor device including a first field-effect transistor including a first gate electrode and a second field-effect transistor including a second gate electrode, the method comprising the steps of:
(a) forming, on a semiconductor region, a silicon gate electrode made of silicon and including a first-gate-electrode region and a second-gate-electrode region;
(b) forming a first trench in a connecting portion between the first-gate-electrode region and the second-gate-electrode region in the silicon gate electrode, leaving a lower portion of the connecting portion between the first-gate-electrode region and the second-gate-electrode region;
(c) forming a metal film on the silicon gate electrode in which the first trench is formed; and
(d) performing heat treatment on the metal film so that the first-gate-electrode region and the second-gate-electrode region are fully silicided to have different metal contents, thereby forming the first gate electrode and the second gate electrode.

31. The method of claim 30, further comprising the step of:
(e) forming, in the first trench, a diffusion preventing film for preventing diffusion of a metal for siliciding the silicon gate electrode, between the steps (b) and (c).

32. The method of claim 30, wherein the diffusion preventing film is made of another metal or a metal compound which is not silicided.

33. The method of claim 30, further comprising the step of:
(f) removing an upper portion of one of the first-gate-electrode region and the second-gate-electrode region in the silicon gate electrode by etching, between the steps of (a) and (c).

34. The method of claim 30, wherein the step (c) includes the step of making the metal film have different thicknesses between portions on the first-gate-electrode region and the second-gate-electrode region in the silicon gate electrode.

35. The method of claim 30, wherein in the step (b), each of the first-gate-electrode region and the second gate electrode exposed from a wall of the first trench has a cross-sectional area larger than that of the connecting portion between the first gate electrode and the second-gate-electrode region.

36. The method of claim 25, further comprising the step of:
(g) selectively forming an isolation region in an upper portion of the semiconductor region, before the step (a),
wherein the step (a) includes the step of forming, on the isolation region, a silicon resistor made of silicon and including a resistor body and a contact region connected to the resistor body,
the step (b) includes the step of forming, in a connecting portion between the resistor body and the contact region in the silicon resistor, a second trench in which at least a portion of each of the resistor body and the contact region is exposed,
the step (c) includes the step of forming the diffusion preventing film in the second trench,
the step (d) includes the step of selectively forming the metal film on the contact region in the silicon resistor in which the diffusion preventing film is formed, and
the step (e) includes the step of fully siliciding the contact region with the metal film through the heat treatment.

37. The method of claim 30, further comprising the step of:
(g) selectively forming an isolation region in an upper portion of the semiconductor region, before the step (a),
wherein the step (a) includes the step of forming, on the isolation region, a silicon resistor made of silicon and including a resistor body and a contact region connected to the resistor body,
the step (b) includes the step of forming, in a connecting portion between the resistor body and the contact region in the silicon resistor, a second trench in which a portion of each of the resistor body and the contact region is exposed,
the step (c) includes the step of selectively forming the metal film on the contact region in the silicon resistor in which the second trench is formed, and
the step (d) includes the step of fully siliciding the contact region with the metal film through the heat treatment.

38. The method of claim 31, wherein the step (e) includes the step of forming the diffusion preventing film in the second trench.
